(19) United States
(12) Patent Application Publication
(10) Pub. No.: US 2026/0132241 A1
(43) Pub. Date: May 14, 2026

(54) MAIN CHAIN SCISSIONABLE BLOCK COPOLYMERS, PHOTORESIST COMPOSITIONS INCLUDING THE SAME, AND PATTERN FORMATION METHODS

(71) Applicant: DuPont Electronic Materials International, LLC, Marlborough, MA (US)

(72) Inventors: Huan He, Hopkinton, MA (US); Sheng Liu, Bow, NH (US); Tomas Marangoni, Orono, ME (US); Joshua Kaitz, Woodinville, WA (US); Emad Aqad, Northborough, MA (US); Mingqi Li, Shrewsbury, MA (US)

(21) Appl. No.: 19/377,435

(22) Filed: Nov. 3, 2025

Related U.S. Application Data
(60) Provisional application No. 63/719,740, filed on Nov. 13, 2024.

(51) Int. Cl. C08F 293/00; G03F 7/039; G03F 7/20

(52) U.S. Cl. CPC C08F 293/005; G03F 7/0392; G03F 7/2002

(57) ABSTRACT

A block copolymer, comprising a center block comprising an acid-labile group in a backbone of the block copolymer; and at least two copolymer arms covalently attached to the center block, wherein each copolymer arm comprises a first repeating unit, and a second repeating unit that is different from the first repeating unit.

### CROSS-REFERENCE TO RELATED APPLICATION

This application claims priority to and the benefit of U.S. Application Ser. No. 63/719,740, filed on Nov. 13, 2024, the content of which is incorporated by reference herein in its entirety.

### FIELD

The present invention relates to block copolymers for photoresist compositions and to pattern formation methods using such photoresist compositions. The invention finds applicability in lithographic applications in the semiconductor manufacturing industry.

### BACKGROUND

Photoresist materials are photosensitive compositions typically used for transferring an image to one or more underlying layers such as a metal, semiconductor, or dielectric layer disposed on a semiconductor substrate. To increase the integration density of semiconductor devices and allow for the formation of structures having dimensions in the nanometer range, photoresists and photolithography processing tools having high-resolution capabilities have been and continue to be developed.

State-of-the-art lithographic patterning processes currently employ ArF (193 nm) immersion scanners to process wafers at dimensions that are less than 60 nanometers (nm). Pushing ArF lithography to sub-60 nm critical dimensions creates several challenges for the photoresist capabilities in terms of process window, line width roughness (LWR), and other critical parameters for high volume manufacturing of integrated circuits. All of these parameters must be addressed in next-generation formulations. As pattern dimensions are reduced in advanced nodes, LWR values have not been concurrently reduced at the same rate, creating a significant source of variation during processing at those leading-edge nodes. Process window improvements are also useful for achieving high yield in integrated circuit manufacturing.

Extreme ultraviolet lithography (EUV lithography) is another leading technology for high volume semiconductor wafer manufacturing at sub-20 nm critical dimensions.

Photoresist polymers are often used in photoresist compositions to achieve useful properties during photolithographic processing. However, the non-uniform distribution of polymer functionality between polymer chains and/or variations along the polymer backbone when using polymers prepared by conventional methods can present challenges when trying to pattern at higher resolutions.

There remains a continued need for photoresist compositions to address one or more problems associated with photolithographic patterning at sub-60 nm critical dimensions. In particular, there is a continuing need for photoresist compositions that can achieve improved resolution and reduced LWR.

### SUMMARY

An aspect provides a block copolymer including a center block comprising an acid-labile group in a backbone of the block copolymer; and at least two copolymer arms covalently attached to the center block, wherein each copolymer arm comprises: a first repeating unit, and a second repeating unit that is different from the first repeating unit.

Another aspect provides a photoresist composition that includes a block copolymer as provided herein and a solvent.

Still another aspect provides a pattern forming method that includes forming on a substrate a photoresist composition layer from the photoresist composition; pattern-wise exposing the photoresist composition layer to activating radiation; and developing the exposed photoresist composition layer to provide a resist relief image.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

As used herein, the term “hydrocarbon” refers to an organic compound or group having at least one carbon atom and at least one hydrogen atom; “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl-O—”; “carboxyl” and “carboxylic acid group” refer to a group having the formula “—C(O)—OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl-O—”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic aromatic ring system that satisfies Huckel's Rule (4n+2π electrons) and includes carbon atoms in the ring; the term “heteroaromatic group” refers to an aromatic group that includes one or more heteroatoms (e.g., 1-4 heteroatoms) selected from N, O, and S instead of a carbon atom in the ring; “aryl” refers to a monovalent monocyclic or polycyclic aromatic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl-O—”; and “arylthio” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl” refers to an alkyl group having at least one heteroatom instead of carbon; “heterocycloalkyl” refers to a cycloalkyl group having 1-4 heteroatoms as ring members instead of carbon; “heterocycloalkylene” refers to a heterocycloalkyl group having a valence of two; “heteroaryl” refers to an aromatic 4-8 membered monocyclic, 8-12 membered bicyclic, or 11-14 membered tricyclic ring system having 1-4 heteroatoms (if monocyclic), 1-6 heteroatoms (if bicyclic), or 1-9 heteroatoms (if tricyclic) that are each independently selected from N, O, S, Si, or P (e.g., carbon atoms and 1-3, 1-6, or 1-9 heteroatoms of N, O, or S, if monocyclic, bicyclic, or tricyclic, respectively). Examples of heteroaryl groups include pyridyl, furyl (furyl or furanyl), imidazolyl, benzimidazolyl, pyrimidinyl, thiophenyl or thienyl, quinolinyl, indolyl, thiazolyl, and the like; and “heteroarylene” refers to a heteroaryl group having a valence of two.

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present. For example, the term “haloalkyl” refers to an alkyl group substituted with one or more halogens. As used herein, “substituted C₁₋₈ haloalkyl” refers to a C₁₋₈ alkyl group substituted with at least one halogen, and is further substituted with one or more other substituent groups that are not halogens. It is to be understood that substitution of a group with a halogen atom is not to be considered a heteroatom-containing group, because a halogen atom does not replace a carbon atom.

Each of the foregoing substituent groups optionally may be substituted unless expressly provided otherwise. The term “optionally substituted” refers to being substituted or unsubstituted. “Substituted” means that at least one hydrogen atom of the chemical structure or group is replaced with another terminal substituent group that is typically monovalent, provided that the designated atom's normal valence is not exceeded. When the substituent is oxo (i.e., O), then two geminal hydrogen atoms on the carbon atom are replaced with the terminal oxo group. It is further noted that the oxo group is bonded to carbon via a double bond to form a carbonyl (C═O), where the carbonyl group is represented herein as —C(O)—. Combinations of substituents or variables are permissible. Exemplary substituent groups that may be present on a “substituted” position include, but are not limited to, nitro (—NO₂), cyano (—CN), hydroxyl (—OH), oxo (O), amino (—NH₂), mono- or di-(C₁₋₆)alkylamino, alkanoyl (such as a C₂₋₆ alkanoyl group such as acyl), formyl (—C(O)H), carboxylic acid or an alkali metal or ammonium salt thereof, esters (including acrylates, methacrylates, and lactones) such as C₂₋₆ alkyl esters (—C(O)O-alkyl or —OC(O)-alkyl) and C₇₋₁₃ aryl esters (—C(O)O-aryl or —OC(O)-aryl); amido (—C(O)NR₂ wherein R is hydrogen or C₁₋₆ alkyl), carboxamido (—CH₂C(O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(O)₂-alkyl), C₆₋₁₂ arylsulfonyl (—S(O)₂-aryl), or tosyl (CH₃C₆H₄SO₂—).

As used herein, when a definition is not otherwise provided, a “divalent linking group” and a “linking group” refer to a group including one or more of —O—, —S—, —Te—, —Se—, —C(O)—, —C(O)O—, —N(R′)—, —C(O)N(R′)—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein each R′ is independently hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —C(O)O—, —N(R′)—, —C(O)N(R′)—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. More typically, the divalent linking group includes at least one of —O—, —C(O)—, —C(O)O—, —N(R′)—, —C(O)N(R′)—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R is hydrogen, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

As used herein, an “acid-labile group” refers to a group in which a bond is cleaved by the action of an acid, optionally and typically with thermal treatment, resulting in formation of a polar group, such as a carboxylic acid or alcohol group. In some instances, the acid-labile group may be formed on a polymer, and optionally and typically with a moiety connected to the cleaved bond becoming disconnected from the polymer. In other systems, a non-polymeric compound may include an acid-labile group that may be cleaved by the action of an acid, resulting in formation of a polar group, such as a carboxylic acid or alcohol group on a cleaved portion of the non-polymeric compound. Such acid is typically a photo-generated acid with bond cleavage occurring during post-exposure baking (PEB); however, embodiments are not limited thereto, and, for example, such acid may be thermally generated. Suitable acid-labile groups include, for example: tertiary alkyl ester groups, secondary or tertiary aryl ester groups, secondary or tertiary ester groups having a combination of alkyl and aryl groups, tertiary alkoxy groups, tertiary carbonate groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

The present invention relates to main chain scissionable block copolymers. Due to the constant scaling down of the semiconductor industry, decreasing the roughness of lithographic patterns has become of crucial importance. In the last decade, multiple approaches to reduce LWR have been attempted, addressing materials (resist, etc.), exposure technology (mask, etc.), and the physics of the processes. From a material perspective, this effort has led to the development of a wide range of materials such as new polymers, photoacid generators (PAGs) and quenchers.

Among the different materials developed, one of the most promising classes of materials in term of LWR, sensitivity, and exposure latitude improvement are de-cross linkable polymers. Such polymers contain a cross-linker unit that decomposes upon exposure or photoacid-catalyzed reaction, substantially decreasing the molecular weight (M_{w}) of the photoresist polymer. Such reduction of M_{w} during exposure induces highly beneficial properties in the photoresist such as improved dissolution of the resist into the developer, improved contrast, improved LWR, and faster photospeed.

Resist polymers having crosslinked polymer chains or sites have been investigated. See for instance U.S. Patent Publications U.S. Pat. No. 7,592,125 B2 and US 2002/0012869 A1, which disclosed crosslinked polymer in which each of the crosslinker moiety has one or more acid labile groups. In the art, resist polymer chain crosslinking was achieved by using a base polymer having one or more crosslinkable functional groups or by using monomer having at least two olefinic polymerizable groups during the copolymerization process. These random and uncontrolled synthesis methods used to produce crosslinked polymers leads to poor inter- and intra-chain homogeneity, structural uncertainty, and relatively higher polydispersity (PDI) in comparison to the conventionally used photoresist polymers (i.e., those with linear structures and without such crosslinking units). Hence, an object of this invention is to provide a new paradigm for crosslinked polymers that enhances polymer homogeneity, achieves lower PDI values, and ensures improved structural consistency.

The inventors have discovered that a block copolymer may be prepared that includes one or more acid-labile group in a backbone of the block copolymer. When the acid cleavable unit is inserted into the main chain of a linear photoresist polymer, it provides a copolymer with improved PDI, monomer composition, and structural uniformity. Such improvement in the polymer main chain physico-chemical properties provides the possibility to decrease the M_{w} of the copolymer upon exposure in a controlled manner to further improve the performances of photoresist lithography.

Provided is a block copolymer that includes a center block that includes an acid-labile group in a backbone of the block copolymer. The block copolymer also includes at least two copolymer arms that are covalently attached to the center block. Each of the copolymer arms includes a first repeating unit and a second repeating unit, wherein the second repeating unit is different from the first repeating unit in each copolymer arm. Each of the copolymer arms may be the same or different. For example, the block copolymer may include a first copolymer arm and a second copolymer arm, wherein the first copolymer arm and the second copolymer arm may be the same or different from each other. Typically, each of the copolymer arms are the same.

In some embodiments, the block copolymer includes a single center block.

In some embodiments, the center block comprises two acid-labile groups.

The block copolymer includes at least two copolymer arms. In some embodiments, the block copolymer includes from two to ten copolymer arms, or from two to eight copolymer arms, or from two to six copolymer arms, or from two to four copolymer arms, or two copolymer arms. Typically, the block copolymer includes two copolymer arms. At least two copolymer arms are covalently bonded to the ends of the center block of the block copolymer. When the block copolymer includes more than two copolymer arms, the additional copolymer arms may be covalently bonded to other locations besides the ends of the center block of the block copolymer.

In some embodiments, the center block may have a structure that is represented by Formula (1), (2), or (3):

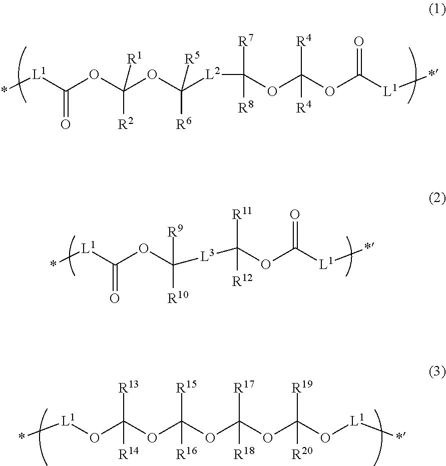

wherein * and *′ each indicates a binding site to a copolymer arm.

In Formula (1), R¹ to R⁴ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl. Typically, R¹ to R⁴ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₆₋₂₀ aryl, or substituted or unsubstituted C₂₋₂₀ heteroaryl.

Each of R¹ to R⁴ optionally further comprises one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (1), optionally, R¹ and R² together form a ring via one or more divalent linking groups, wherein each of the one or more divalent linking groups is substituted or unsubstituted, and wherein the ring is substituted or unsubstituted, and/or R³ and R⁴ together form a ring via one or more divalent linking groups, wherein each of the one or more divalent linking groups is substituted or unsubstituted, and wherein the ring is substituted or unsubstituted.

In Formula (1), R⁵ to R⁸ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl. Typically, R⁵ to R⁸ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl.

Each of R⁵ to R⁸ optionally further comprises one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (1), optionally, R⁵ and R⁶ together form a ring via one or more divalent linking groups, wherein each of the one or more divalent linking groups is substituted or unsubstituted, and wherein the ring is substituted or unsubstituted. In Formula (1), optionally, R⁷ and R⁸ together form a ring via one or more divalent linking groups, wherein each of the one or more divalent linking groups is substituted or unsubstituted, and wherein the ring is substituted or unsubstituted.

In Formula (1), optionally, R¹ and R⁵ together form a ring via one or more divalent linking groups, wherein each of the one or more divalent linking groups is substituted or unsubstituted, and wherein the ring is substituted or unsubstituted. In Formula (1), optionally, R² and R⁶ together form a ring via one or more divalent linking groups, wherein each of the one or more divalent linking groups is substituted or unsubstituted, and wherein the ring is substituted or unsubstituted. In Formula (1), optionally, R³ and R⁷ together form a ring via one or more divalent linking groups, wherein each of the one or more divalent linking groups is substituted or unsubstituted, and wherein the ring is substituted or unsubstituted. In Formula (1), optionally, R⁴ and R⁸ together form a ring via one or more divalent linking groups, wherein each of the one or more divalent linking groups is substituted or unsubstituted, and wherein the ring is substituted or unsubstituted.

In Formula (2), R⁹ to R¹² are each independently substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl. Typically, R⁹ to R¹² are each independently substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₆₋₂₀ aryl, or substituted or unsubstituted C₂₋₂₀ heteroaryl.

In Formula (2), optionally, R⁹ and R¹⁰ together form a ring via one or more divalent linking groups, wherein each of the one or more divalent linking groups is substituted or unsubstituted, and wherein the ring is substituted or unsubstituted. In Formula (2), optionally, R¹¹ and R¹² together form a ring via one or more divalent linking groups, wherein each of the one or more divalent linking groups is substituted or unsubstituted, and wherein the ring is substituted or unsubstituted. In Formula (2), optionally, R⁹ and R¹¹ together form a ring via one or more divalent linking groups, wherein each of the one or more divalent linking groups is substituted or unsubstituted, and wherein the ring is substituted or unsubstituted. In Formula (2), optionally, R¹⁰ and R¹² together form a ring via one or more divalent linking groups, wherein each of the one or more divalent linking groups is substituted or unsubstituted, and wherein the ring is substituted or unsubstituted.

In Formula (3), R¹³, R¹⁴, R¹⁹, and R²⁰ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃-20 cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl. Typically, R¹³, R¹⁴, R¹⁹, and R²⁰ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₆₋₂₀ aryl, or substituted or unsubstituted C₂₋₂₀ heteroaryl.

Each of R¹³, R¹⁴, R¹⁹, and R²⁰ optionally further comprises one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (3), optionally, R¹³ and R¹⁴ together form a ring via one or more divalent linking groups, and/or R¹⁹ and R²⁰ together form a ring via one or more divalent linking groups. Each of the one or more divalent linking groups is substituted or unsubstituted, and wherein the ring is substituted or unsubstituted.

In Formula (3), R¹⁵ to R¹⁸ are each hydrogen, deuterium, substituted or unsubstituted C₁₋₂₀ alkyl, substituted or unsubstituted C₃-20 cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl. Typically, R¹⁵ to R¹⁸ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl.

Each of R¹⁵ to R¹⁸ optionally further comprises one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (3), R¹⁵ and R¹⁶ optionally together form a ring via one or more divalent linking groups, and/or R¹⁷ and R¹⁸ together form a ring via one or more divalent linking groups. Each of the one or more divalent linking groups is substituted or unsubstituted, and wherein the ring is substituted or unsubstituted.

In Formula (3), optionally R¹³ and R¹⁵ together form a ring via one or more divalent linking groups, R¹⁴ and R¹⁶ together form a ring via one or more divalent linking groups, R¹⁷ and R¹⁹ together form a ring via one or more divalent linking groups, and/or R¹⁸ and R²⁰ together form a ring via one or more divalent linking groups. Each of the one or more divalent linking groups is substituted or unsubstituted, and wherein the ring is substituted or unsubstituted.

In Formulae (1) to (3), each L¹ is independently a divalent linking group that includes at least one carbon atom. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, provided that L¹ includes at least one carbon atom, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. For example, each L¹ independently may be a substituted or unsubstituted C₁₋₃₀ alkylene, a substituted or unsubstituted C₃₋₃₀ cycloalkylene, a substituted or unsubstituted C₆₋₃₀ arylene, or substituted or unsubstituted C₃₋₃₀ heteroarylene.

In some embodiments, L¹ does not include sulfur.

In Formulae (1) and (3), L² and L⁴ are each independently a divalent linking group. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (2), L³ is a single bond or one or more divalent linking groups. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In some embodiments, the center block may have a structure represented by one of Formulae (1a), (1b), (2a), (2b), or (2c):

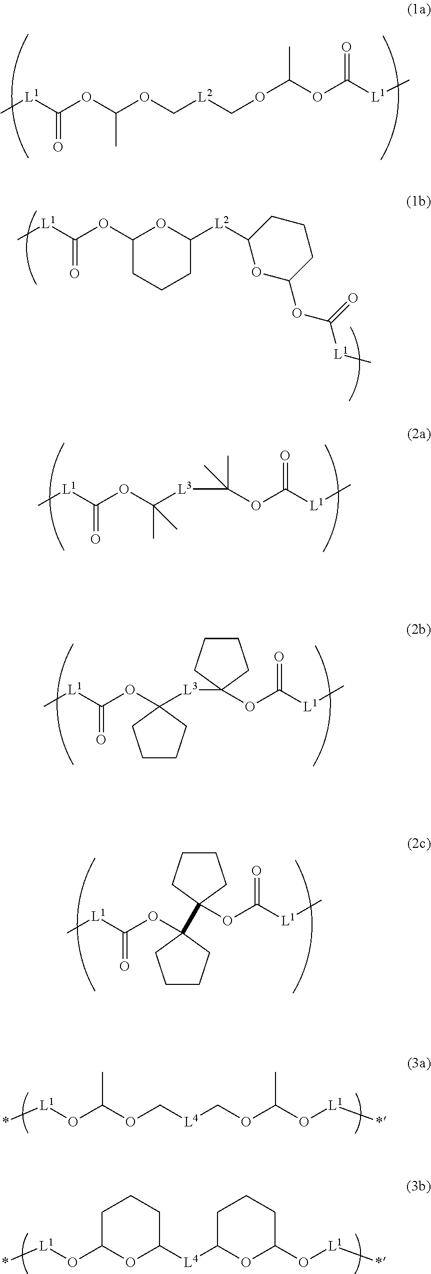

wherein L¹, L², and L³ are each as defined in Formulae (1) and (2).

Non-limiting examples of the center block include the following:

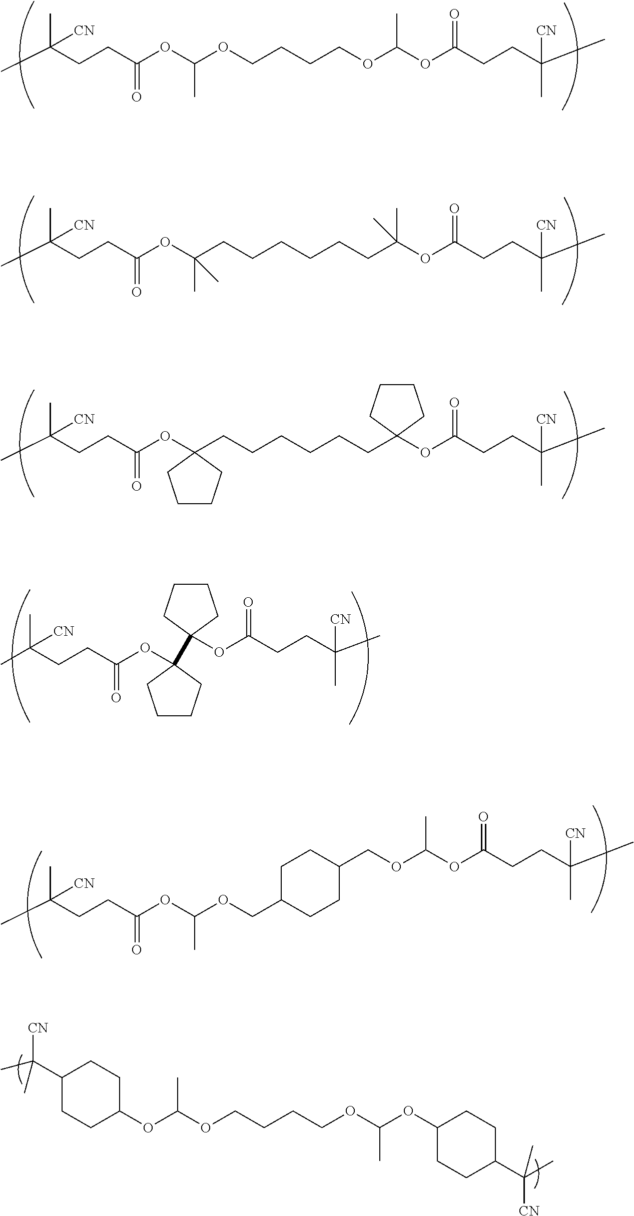

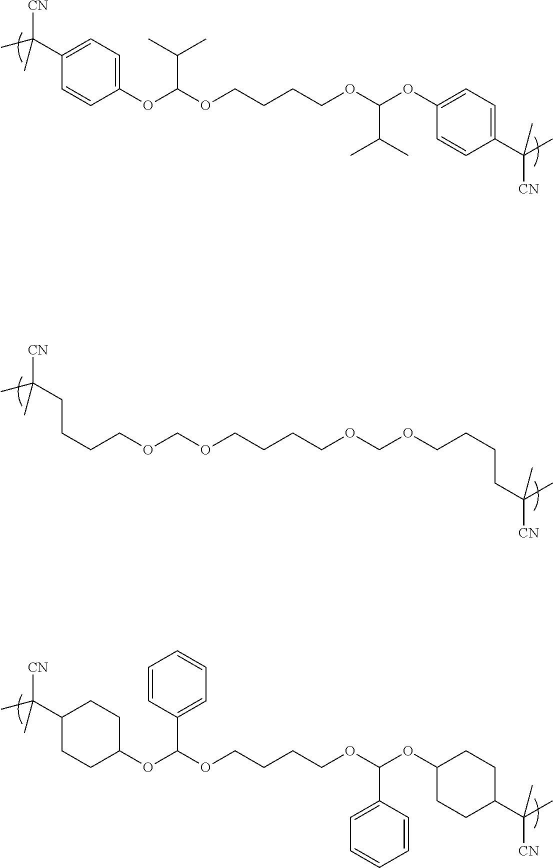

The block copolymer further includes at least two copolymer arms that are covalently attached to the center block. Each copolymer arm includes a first repeating unit and a second repeating unit, wherein the first repeating unit and the second repeating unit are different from each other.

In some embodiments, the first repeating unit may include an acid-labile group. Suitable acid decomposable or labile groups include, for example, tertiary alkyl ester groups, secondary or tertiary aryl ester groups, secondary or tertiary ester groups having a combination of alkyl and aryl groups, tertiary alkoxy groups, acetal groups, ketal groups, tertiary carbonate groups, and tertiary carbamate groups. Typically, the acid labile group may be an acetal group, a ketal group, a tertiary carbonate group, a tertiary carbamate group, or a tertiary ester group. As used herein, the “tertiary carbamate group” includes tertiary carbamate ester groups having alkyl groups, tertiary carbamate ester groups having aryl groups, and tertiary carbamate ester groups having a combination of alkyl and aryl groups. As used herein, the “tertiary carbonate group” includes tertiary carbonate ester groups having alkyl groups, tertiary carbonate ester groups having aryl groups, and tertiary carbonate ester groups having a combination of alkyl and aryl groups. Preferably, the acid liable group includes a tertiary ester group.

Exemplary repeating units having an acid labile group include those represented by one or more of Formulae (4) to (8):

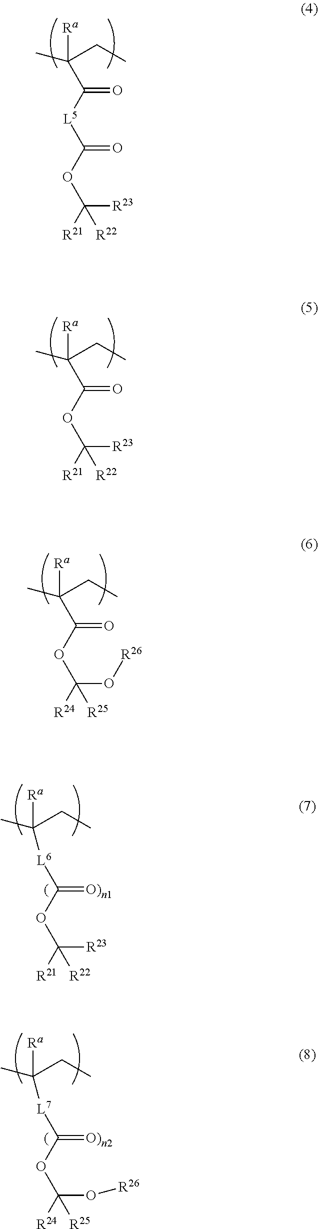

In Formulae (4) to (8), each R^{a} is independently hydrogen, deuterium, fluorine, cyano, substituted or unsubstituted C₁₋₁₀ alkyl, or substituted or unsubstituted C₁₋₁₀ fluoroalkyl. Preferably, R^{a} is hydrogen, fluorine, or substituted or unsubstituted C₁₋₅ alkyl, typically methyl.

In Formula (4), L⁵ is a divalent linking group. For example, L⁵ may be a divalent linking group including at least one carbon atom, at least one heteroatom, or a combination thereof. For example, L⁵ may include 1 to 10 carbon atoms and at least one heteroatom. In one or more embodiments, L⁵ may be —OCH₂—, —OCH₂CH₂O— or —N(R^{c})—, wherein R^{c} is hydrogen, deuterium, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

In Formulae (4), (5), and (7), R²¹ to R²³ may each independently be hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl; provided that only one of R²¹ to R²³ may be hydrogen, and provided that when one of R²¹ to R²³ is hydrogen, one or both of the others of R²¹ to R²³ are substituted or unsubstituted C₆₋₂₀ aryl or substituted or unsubstituted C₄₋₂₀ heteroaryl. Preferably, R²¹ to R²³ are each independently substituted or unsubstituted C₁₋₆ alkyl or substituted or unsubstituted C₃₋₁₀ cycloalkyl.

In Formulae (4), (5), and (6), any two of R²¹ to R²³ together optionally form a ring, and each of R²¹ to R²³ optionally may include as part of their structure one or more groups chosen from —O—, —C(O)—, —N(R^{c})—, —S—, —S(O)—, or —S(O)₂—, wherein R^{c} may be hydrogen, deuterium, a straight chain or branched C₁₋₂₀ alkyl, monocyclic or polycyclic C₃₋₂₀ cycloalkyl, or monocyclic or polycyclic C₁₋₂₀ heterocycloalkyl. For example, any one or more of R²¹ to R²³ may be independently a group of the formula —CH₂C(═O)CH₍₃₋ₙ₎Yₙ, where each Y is independently substituted or unsubstituted C₁₋₃₀ heterocycloalkyl, and n is 1 or 2. For example, each Y may be independently substituted or unsubstituted C₁₋₃₀ heterocycloalkyl including a group of the formula —O(C^{a1})(C^{a2})O—, wherein C^{a1} and C^{a2} are each independently hydrogen, deuterium or substituted or unsubstituted C₁₋₁₀ alkyl, and where C^{a1} and C^{a2} together optionally form a ring.

In Formulae (6) and (8), R²⁴ and R²⁵ may be each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₆₋₂₀ aryl, or substituted or unsubstituted C₂₋₂₀ heteroaryl; and R²⁶ may be substituted or unsubstituted C₁₋₂₀ alkyl, substituted or unsubstituted C₃₋₂₀ cycloalkyl, or substituted or unsubstituted C₁₋₃₀ heterocycloalkyl. Optionally, one of R² or R²⁵ together with R²⁶ may form a heterocyclic ring. Preferably, R²⁴ and R²⁵ may be each independently hydrogen, deuterium, substituted or unsubstituted C₁₋₂₀ alkyl, substituted or unsubstituted C₃₋₂₀ cycloalkyl, or substituted or unsubstituted C₁₋₂₀ heterocycloalkyl.

In Formulae (7) and (8), L⁶ and L⁷ are each independently a single bond or a divalent linking group. Preferably, L⁶ and L⁷ are each independently substituted or unsubstituted C₆₋₃₀ arylene or substituted or unsubstituted C₃₋₃₀ cycloalkylene. For example, in some embodiments, L⁷ does not include a (meth)acrylate group as part of its structure.

In Formulae (7) and (8), each of n1 and n2 may independently be 0 or 1. It is to be understood that when n1 or n2 is 0, the corresponding L⁶ or L⁷ group is connected directly to the respective oxygen atom.

Non-limiting examples of repeating units having an acid labile group include the following:

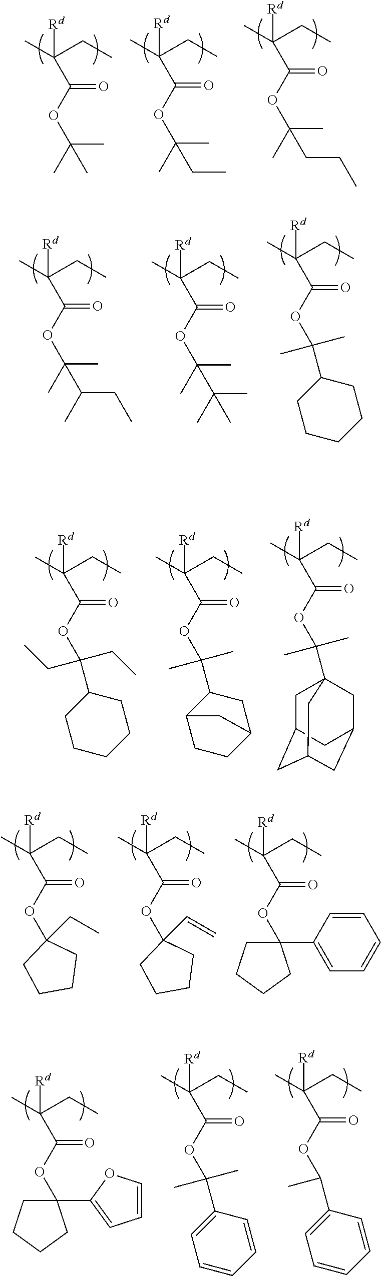

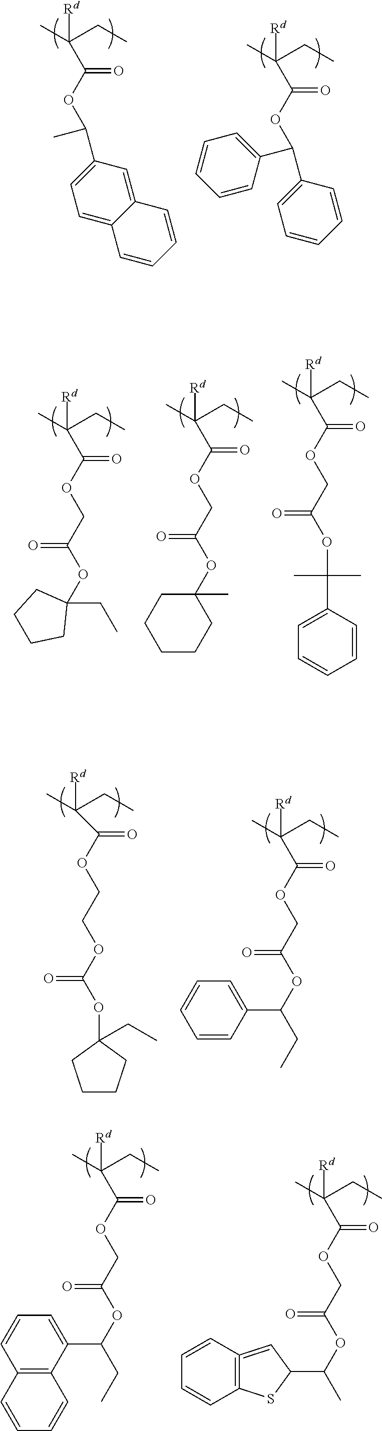

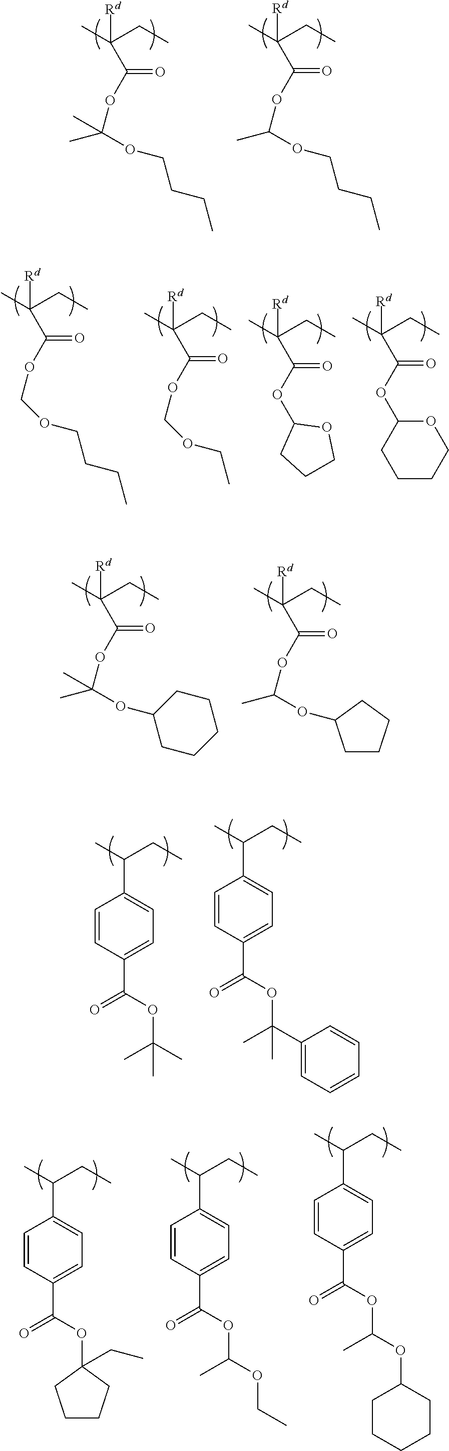

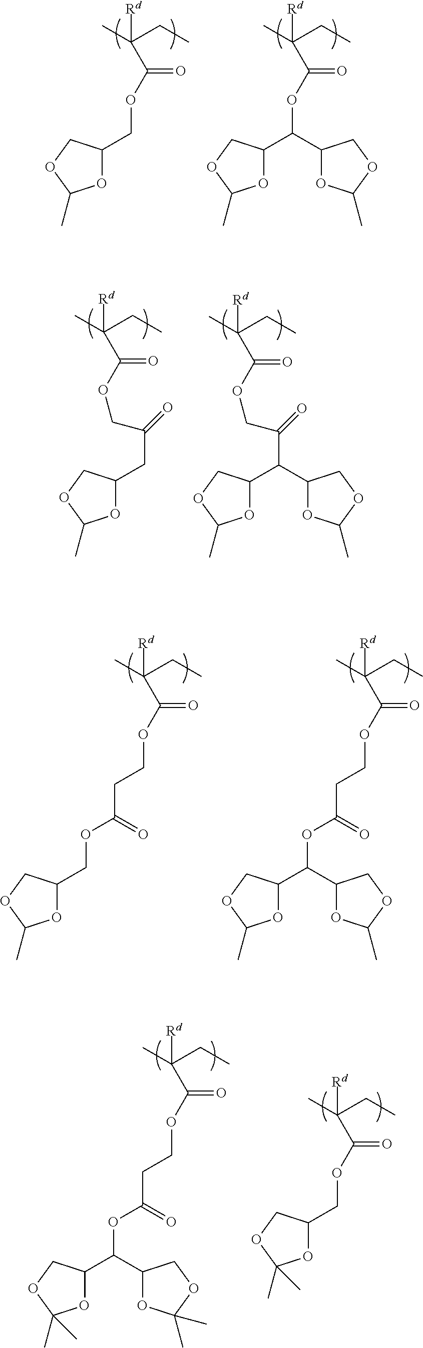

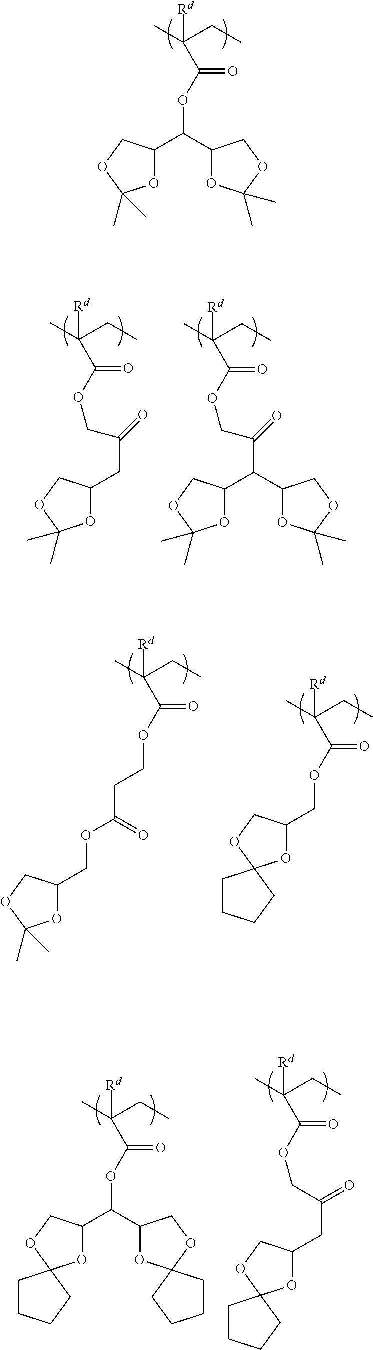

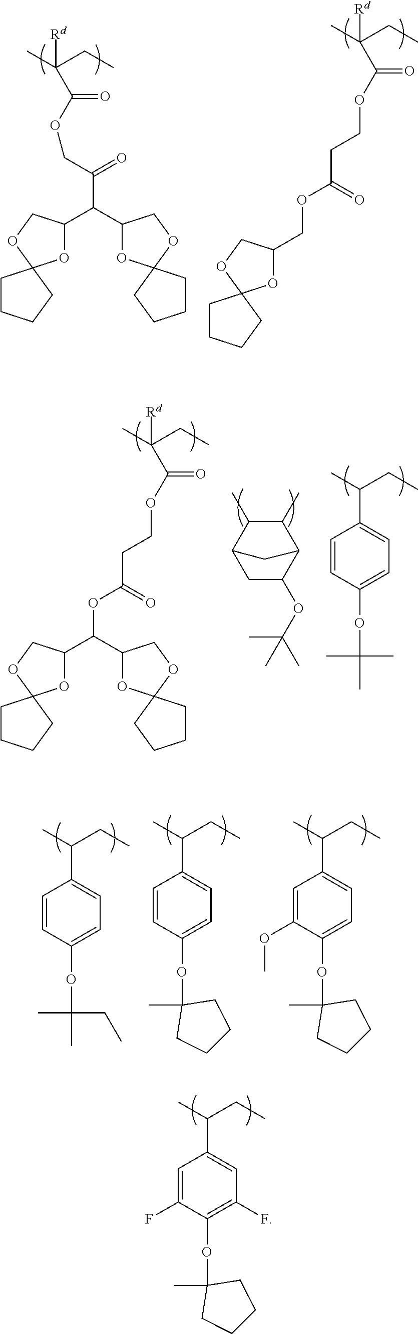

wherein R^{d} is hydrogen, deuterium, halogen, substituted or unsubstituted C₁₋₆ alkyl, or substituted or unsubstituted C₃₋₆ cycloalkyl.

The repeating unit having an acid-labile group may be present in the copolymer arm in an amount from 25 to 75 mol %, more typically from 25 to 65 mol %, still more typically from 30 to 60 mol %, based on total repeating units in the copolymer arm.

The copolymer arm further includes a second repeating unit. In some embodiments, the second repeating unit may be a polar repeating unit. Exemplary polar groups include a cyano group, a sultone group, a sulfonamide group, a hydroxyalkyl group, a hydroxycycloalkyl group, a hydroxyaryl group, a lactone group, or a combination thereof.

In some embodiments, the second repeating unit includes a lactone group. For example, the second repeating may include a lactone group that is represented by Formula (9):

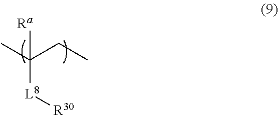

In Formula (9), R^{a} may be hydrogen, deuterium, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formula (9), L⁸ may be a single bond or one or more divalent linking groups. For example, L⁸ may be one or more of —O—, —C(O)—, —C(O)O—, —N(R^{c})—, —C(O)N(R^{c})—, substituted or unsubstituted C₁₋₁₀ alkylene, substituted or unsubstituted C₃₋₁₀ cycloalkylene, substituted or unsubstituted C₃₋₁₀ zeterocycloalkylene, substituted or unsubstituted C₆₋₁₀ arylene, substituted or unsubstituted C₃₋₁₀ heteroarylene, or a combination thereof, wherein R^{c} may be hydrogen, deuterium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L⁸ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (9), R³⁰ is a monocyclic, polycyclic, or fused polycyclic C₄₋₂₀ lactone-containing group.

Non-limiting examples of lactone-containing repeating units of Formula (9) may include:

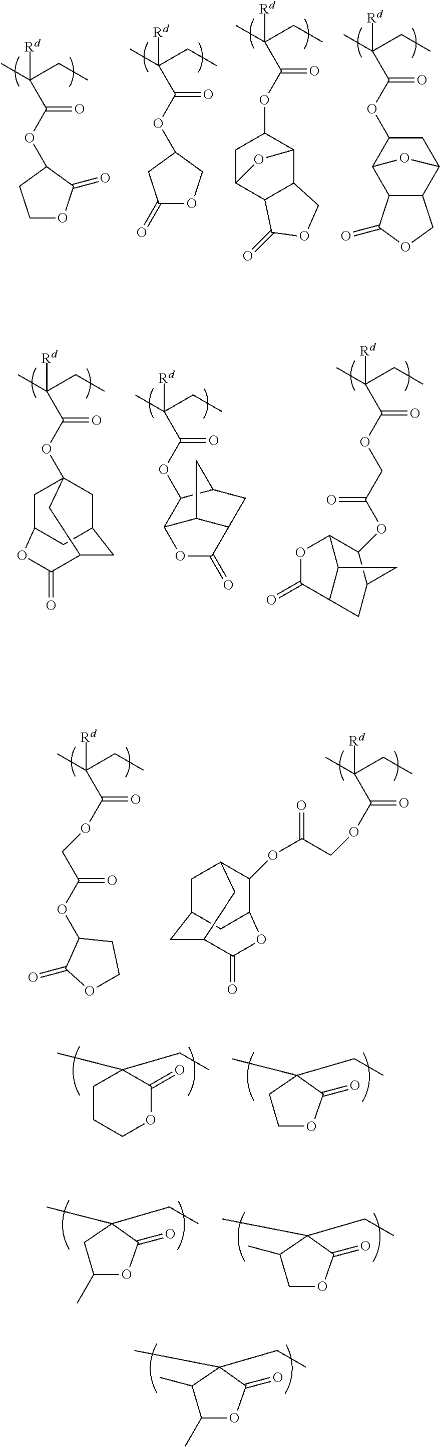

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

A repeating unit including a lactone group typically may be present in an amount from 5 to 90 mol %, more typically from 10 to 75 mol %, and still more typically from 15 to 70 mol %, based on total repeating units of the copolymer arm. The repeating units including a lactone group typically may be present in the polymer in an amount from 5 to 90 mol %, more typically from 10 to 75 mol %, and still more typically from 15 to 70 mol %, based on total repeating units of the copolymer arm.

A repeating unit of the copolymer arm may include a hydroxyaryl group. Exemplary hydroxyaryl groups include a phenolic group or a naphtholic group. For example, a repeating unit of the copolymer arm may include a hydroxyaryl group that is represented by Formula (10).

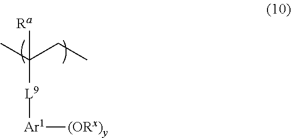

In Formula (10), R^{a} may be hydrogen, deuterium, fluorine, cyano, or substituted or unsubstituted C₁₋₁₀ alkyl. Preferably, R^{a} may be hydrogen, deuterium, fluorine, or substituted or unsubstituted C₁₋₅ alkyl, typically hydrogen or methyl.

In Formula (10), L⁹ may be a single bond or one or more divalent linking groups. For example, L⁹ may be —O—, —C(O)—, —C(O)O—, —N(R^{c})—, —C(O)N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L⁹ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (10), Ar¹ may be a substituted C₅₋₆₀ aromatic group that optionally includes one or more aromatic ring heteroatoms chosen from N, O, S, or a combination thereof, wherein the aromatic group may be monocyclic, non-fused polycyclic, or fused polycyclic. When the C₅₋₆₀ aromatic group is polycyclic, the ring or ring groups may be fused (such as naphthyl or the like), non-fused, or a combination thereof. When the polycyclic C₅₋₆₀ aromatic group is non-fused, the ring or ring groups may be directly linked (such as biaryls, biphenyl, or the like) or may be bridged by a heteroatom (such as triphenylamino or diphenylene ether). In some aspects, the polycyclic C₅₋₆₀ aromatic group may include a combination of fused rings and directly linked rings (such as binaphthyl or the like).

In Formula (10), y may be an integer from 1 to 12, preferably from 1 to 6, and typically from 1 to 3.

In Formula (10), each R^{x} may independently be hydrogen or methyl, provided that at least one R^{x} is hydrogen.

Non-limiting examples of such repeating units of Formula (10) may include:

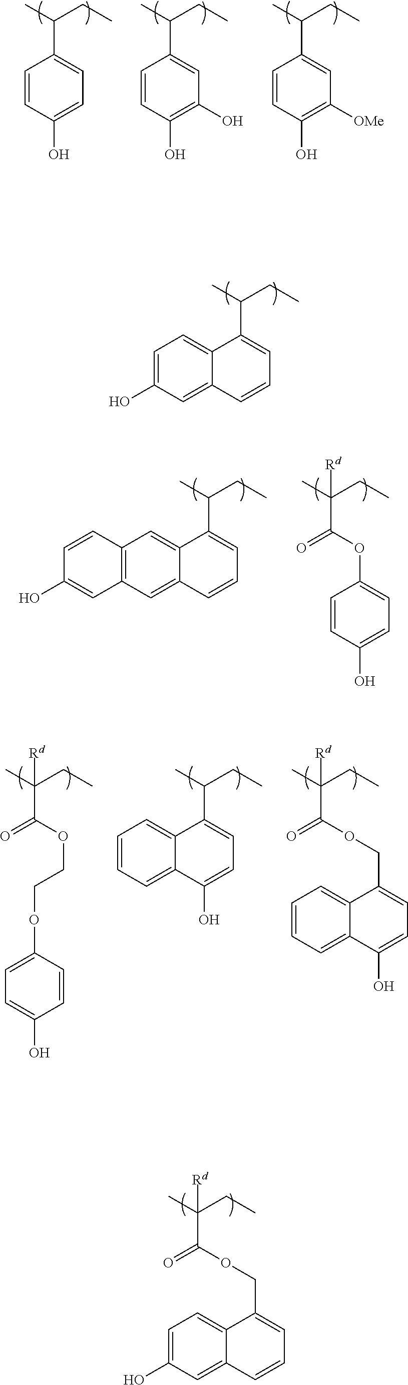

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit in the copolymer arms including a hydroxyaryl group typically may be present in an amount from 10 to 90 mole percent (mol %), more typically from 15 to 75 mol %, and still more typically from 20 to 70 mol %, based on total repeating units of the copolymer arm. The repeating units including a hydroxyaryl group typically may be present in the copolymer arm in an amount from 10 to 90 mol %, more typically from 15 to 75 mol %, and still more typically from 25 to 70 mol %, based on total repeating units of the copolymer arm.

Other repeating units of the polymer may include a polar group that is represented by Formula (11):

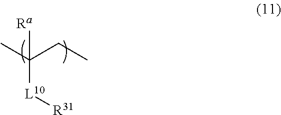

In Formula (11), R^{a} may be hydrogen, deuterium, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formulae (11), L¹⁰ may be a single bond or one or more divalent linking groups. For example, L¹⁰ may be —O—, —C(O)—, —C(O)O—, —N(R^{c})—, —C(O)N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, deuterium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L¹⁰ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (11), R³¹ may be substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or substituted or unsubstituted poly(C₁₋₃ alkylene oxide). The substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of a sulfonamide group (e.g., —NHSO₂CF₃), a hydroxy group (—OH), —S(O)—, —S(O₂)—, or a fluoroalcohol group (e.g., —C(CF₃)₂OH).

Non-limiting examples of repeating units of Formula (11) may include:

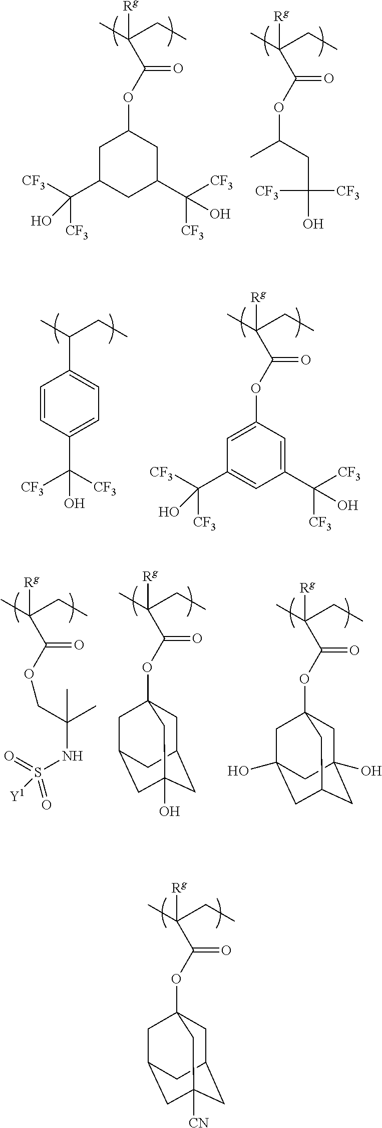

wherein R^{g} may be hydrogen, deuterium, fluorine, cyano, or substituted or unsubstituted C₁₋₁₀ alkyl. Preferably, R^{g} may be hydrogen, fluorine, or substituted or unsubstituted C₁₋₅ alkyl, typically methyl. Y¹ may be F or C₁₋₄ perfluoroalkyl.

Unless noted otherwise, the second repeating unit in the copolymer arms including a polar group typically may be present in an amount from 10 to 90 mole percent (mol %), more typically from 15 to 75 mol %, and still more typically from 20 to 70 mol %, based on total repeating units of the copolymer arm. The repeating units including a polar group typically may be present in the copolymer arm in an amount from 10 to 90 mol %, more typically from 15 to 75 mol %, and still more typically from 25 to 70 mol %, based on total repeating units of the copolymer arm.

The copolymer arms may further include one or more additional (e.g., third) repeating units. The repeating units may be, for example, one or more units for purposes of adjusting properties of the composition, such as etch rate and solubility. Exemplary repeating units may include those derived from one or more of (meth)acrylate, vinyl aromatic, vinyl ether, vinyl ketone, and/or vinyl ester monomers. For example, the copolymer arms may include one or more repeating units that include a functional group selected from a base-solubilizing group, a crosslinkable group, a crosslinking group, or the like, or a combination thereof.

A repeating unit of the copolymer arm may include a salt group. As used herein, a “salt group” refers to a moiety having a positive charge and/or a negative charge, such as having a positively charged or negatively charged moiety that is bonded pendant to the backbone of the block copolymer. The repeating unit of the copolymer arm including a salt group may comprise a photoacid generator (PAG) group or a photo-decomposable quencher (PDQ) group.

For example, a repeating unit of the copolymer arm may include a salt group that is represented by Formulae (12a) or (12b):

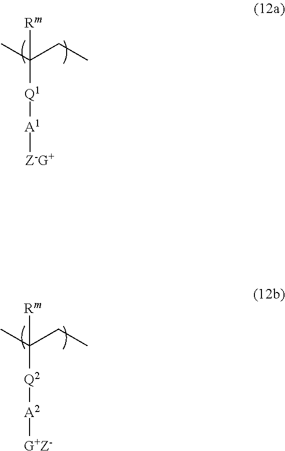

In Formulae (12a) and (12b), each R^{m} may be hydrogen, deuterium, fluorine, cyano, or substituted or unsubstituted C₁₋₁₀ alkyl. Preferably, R^{m} is hydrogen, fluorine, or substituted or unsubstituted C₁₋₅ alkyl, typically methyl.

In Formulae (12a) and (12b), Q¹ and Q² may each be independently a single bond or a divalent linking group. Preferably, Q¹ and Q² may each independently include 1 to 10 carbon atoms and at least one heteroatom, more preferably —C(O)—O—.

In Formulae (12a) and (12b), A¹ and A² may be each independently one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, or substituted or unsubstituted C₃₋₃₀ heteroarylene. In some embodiments, A¹ and A² may be each independently a divalent C₁₋₃₀ perfluoroalkylene group that is optionally substituted.

In Formula (12a), Z⁻ is an anionic moiety that is bonded to A¹, the conjugated acid of which typically has a pKa from −15 to 10. Z⁻ may be a sulfonate, a carboxylate, an anion of a sulfonamide, an anion of a sulfonimide, or a methide anion.

In Formula (12a), G⁺ is an organic cation as defined herein. In some embodiments, G⁺ is an iodonium cation substituted with two alkyl groups, two aryl groups, or a combination of alkyl and aryl groups; or a sulfonium cation substituted with three alkyl groups, three aryl groups, or a combination of alkyl and aryl groups.

In Formula (12b), Z⁻ is an anion compound as defined herein, the conjugated acid of which typically has a pKa from −15 to 10. Z may be a sulfonate, a carboxylate, an anion of a sulfonamide, an anion of a sulfonimide, or a methide anion species. For example, Z⁻ may be as defined herein for the anions A⁻.

In Formula (12b), G⁺ is an organic cation that is bonded to A². For example, G⁺ may include an iodonium cation substituted with two alkyl groups, two aryl groups, or a combination of alkyl and aryl groups; or a sulfonium cation substituted with three alkyl groups, three aryl groups, or a combination of alkyl and aryl groups.

In still other embodiments, when the copolymer arm includes a repeating unit having a salt group, the copolymer arm may include a zwitterionic species. For example, the copolymer arm may include repeating units having a salt group of the Formula (12c):

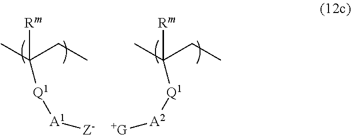

wherein, in Formula (12c), each R^{m} is independently as defined for Formulae (10a) and (10b).

In Formula (12c), Q¹, A¹, and Z⁻ are as defined in Formula (12a), and Q², A², and G are as defined in Formula (12b).

Exemplary repeating units of Formula (12a) include the following:

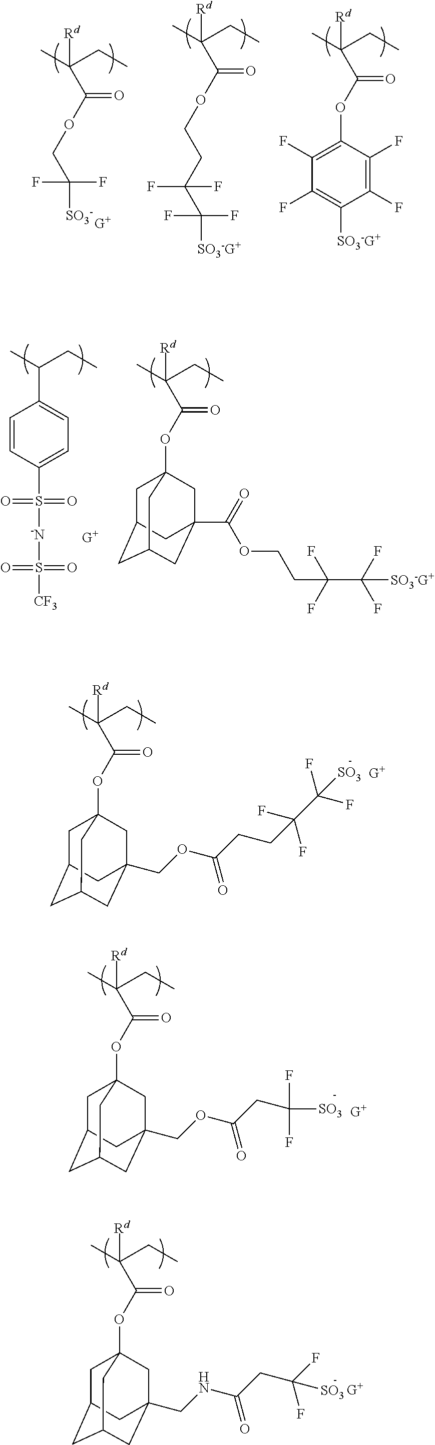

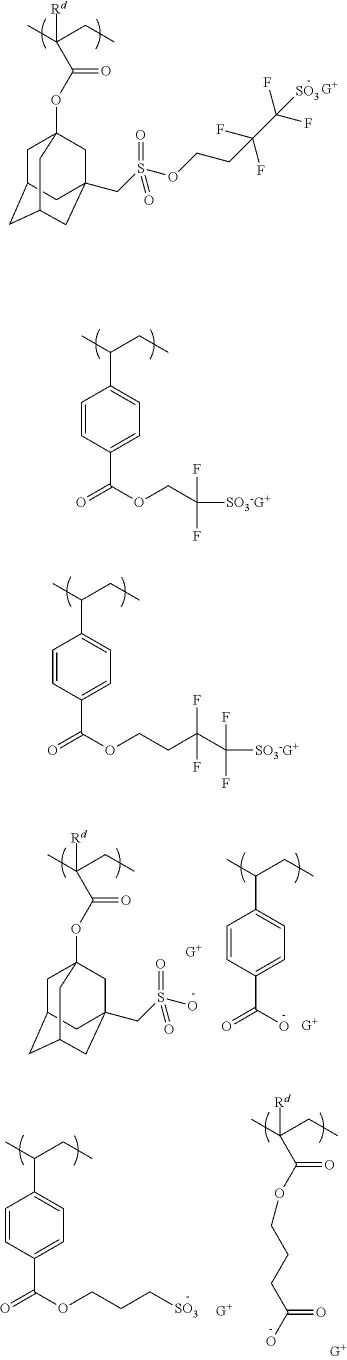

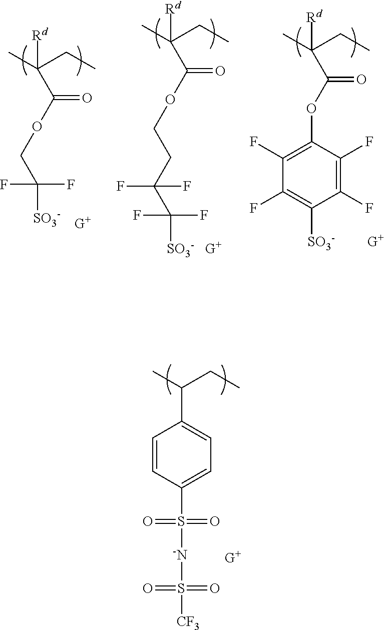

wherein G is the organic cation, and each R^{d} is independently as defined for Formulae (12a).

Exemplary repeating units of Formula (12b) include the following:

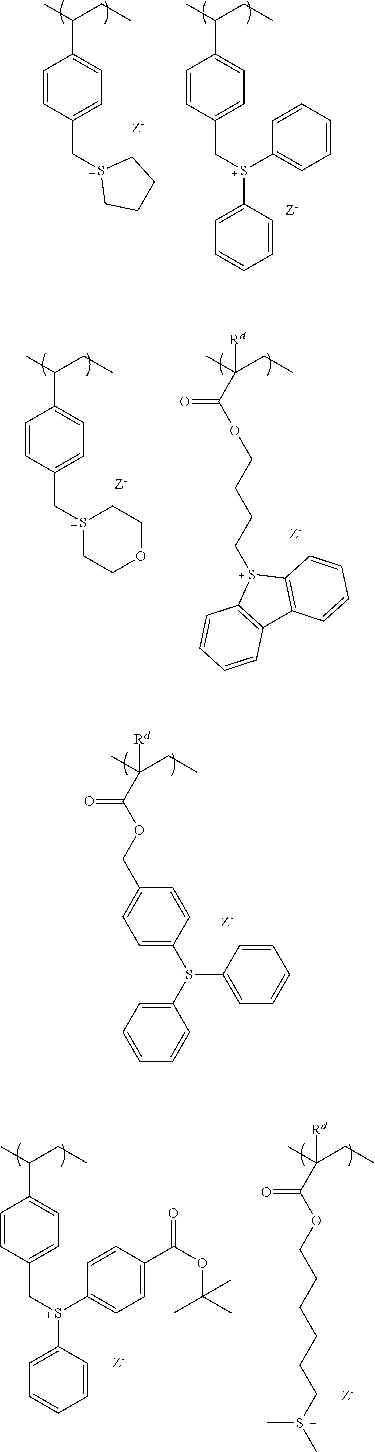

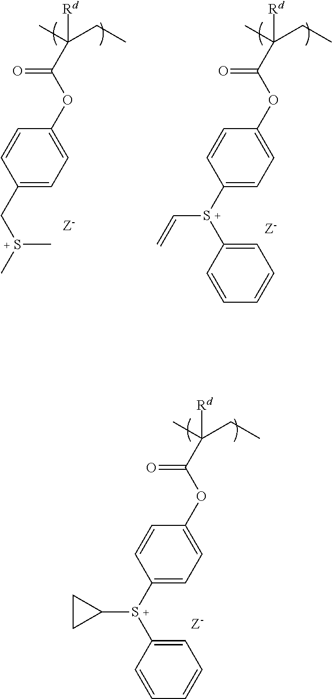

wherein Z⁻ is an anion group as defined herein, and each R^{d} is independently as defined for Formulae (12b).

The repeating unit of the copolymer arm including a salt typically may be present in an amount from 1 to 35 mol %, typically from 1 to 25 mol %, more typically from 2 to 15 mol %, based on total repeating units of the copolymer arm.

In some embodiments, the copolymer arm may include a repeating unit that includes an acid group. Exemplary acid groups include a carboxylic acid group. A repeating unit of the copolymer arm may include an acid group that is represented by Formula (13):

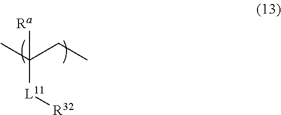

In Formula (13), R^{a} may be hydrogen, deuterium, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formula (13), L¹¹ may be a single bond or one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₃₋₃₀ heteroarylalkyl, or —C(O)—O—.

In Formula (13), R³² may be —C(O)—OH.

Non-limiting examples of repeating units of Formula (13) may include:

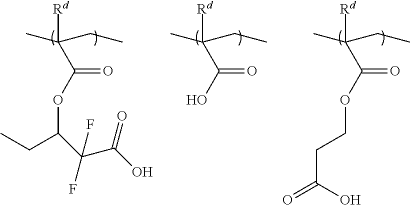

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit including an acid group typically may be present in an amount from 1 to 20 mol %, more typically from 5 to 20 mol %, and still more typically from 5 to 10 mol %, based on total repeating units of the copolymer arm.

Non-limiting exemplary copolymer arms of the present invention include one or more of the following:

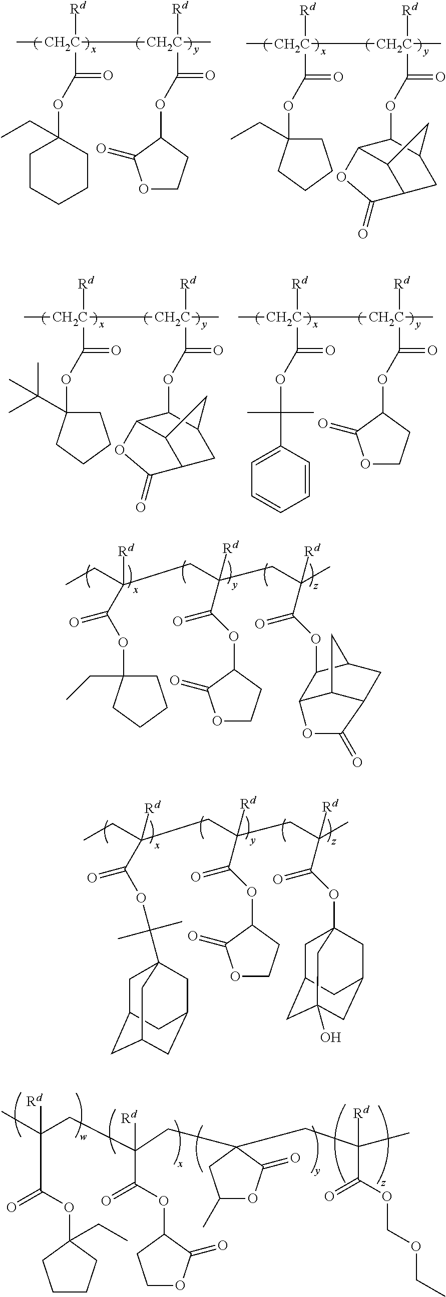

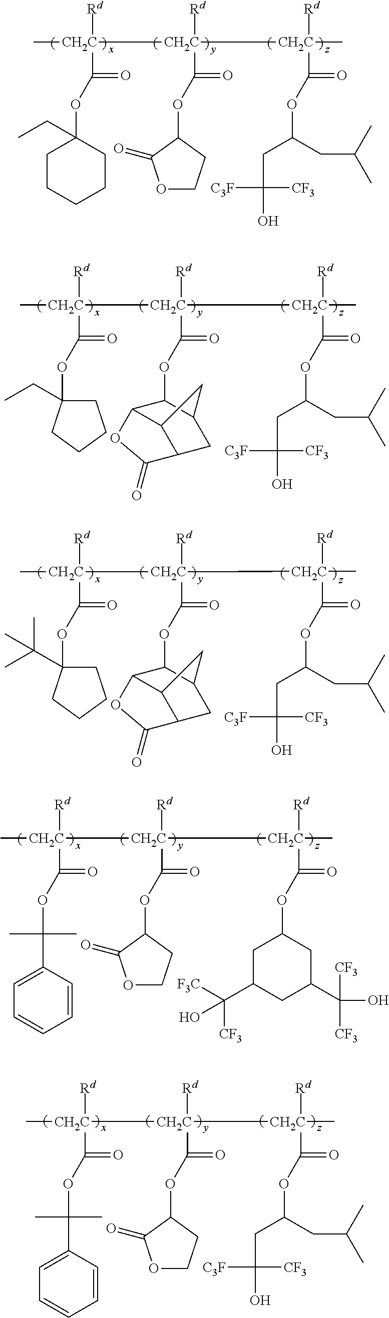

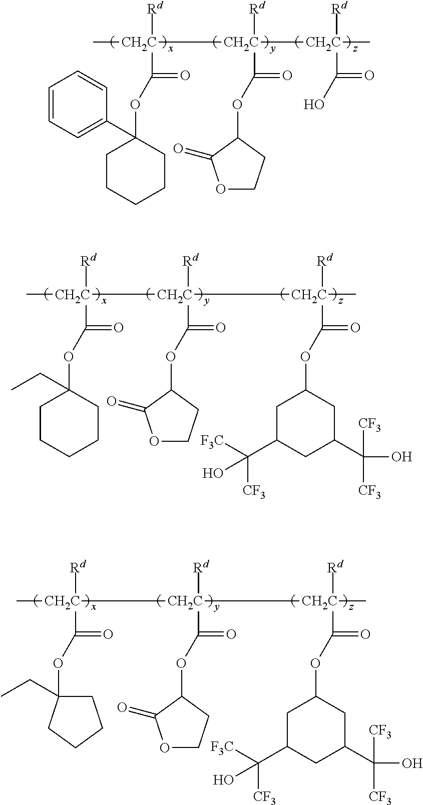

wherein each of w, x, y and z is a molar fraction of an associated repeating unit, wherein the sum of the molar fractions for each copolymer arm adds up to 1, and wherein each R^{d} is independently hydrogen, deuterium, halogen, substituted or unsubstituted C₁₋₆ alkyl, or substituted or unsubstituted C₃₋₆ cycloalkyl.

In some embodiments, each of the copolymer arms may be a block copolymer. When the copolymer arms are present as block copolymers themselves, an average number of blocks of copolymer arms may be from 2 to 10 on each end of the center unit, typically, from 2 to 5 on each end of the center block.

When the copolymer arms are present as block copolymers themselves, an average number of repeating units within each block may be 5 or more. Typically, the average number of polymerized units within each block may be 10 or more, or 20 or more, or 100 or more. For example, a triblock copolymer arm that includes three blocks of repeating units can have 15 or more, or 30 or more, or 75 or more, or 150 or more total repeating units.

The block copolymer typically has a weight average molecular weight (M_{w}) from 2,500 to 50,000 grams per mole (g/mol), preferably from 2,500 to 30,000 g/mol, more preferably 2,500 to 20,000 g/mol, and still more preferably from 2,500 to 15,000 g/mol. The dispersity index (D) of the block copolymer, which is the ratio of M_{w} to Mₙ, is typically from 1.1 to 3, more typically from 1.1 to 2, and preferably from 1.1 to 1.7, 1.1 to 1.6, or 1.1 to 1.4 (Mₙ is number average molecular weight). Molecular weights are determined by gel permeation chromatography (GPC) using polystyrene standards.

The block copolymer may be prepared using any suitable method(s) in the art. For example, one or more monomers corresponding to the reacted and/or polymerized units described herein may be combined, or fed separately, using suitable solvent(s) and initiator, and polymerized in a reactor. For example, the block copolymer may be obtained by polymerization of the respective central monomer and monomers corresponding to the copolymer arms under any suitable conditions, such as by heating at an effective temperature, irradiation with actinic radiation at an effective wavelength, or a combination thereof.

Each monomer corresponding to the repeating units described herein independently comprises a polymerizable group having a carbon-carbon unsaturated vinylic group, and typically may be selected from a substituted or unsubstituted C₂₋₂₀ alkenyl group, a substituted or unsubstituted norbornyl group, a substituted or unsubstituted (meth)acrylic group, a substituted or unsubstituted vinyl ether group, a substituted or unsubstituted vinyl ketone group, a substituted or unsubstituted vinyl ester group, a substituted or unsubstituted vinyl aromatic group, or a substituted or unsubstituted vinyl sulfonate group. Typically, the polymerizable group of each monomer is independently substituted or unsubstituted C₂₋₂₀ alkenyl, substituted or unsubstituted norbornyl, substituted or unsubstituted (meth)acrylic, or substituted or unsubstituted vinyl aromatic. Preferably, the polymerizable group of each monomer is independently substituted or unsubstituted (meth)acrylic, or substituted or unsubstituted vinyl aromatic.

The block copolymers can be prepared using living or controlled free radical polymerization techniques, including reversible addition fragmentation chain transfer polymerization (RAFT), nitroxide mediated polymerization (NMP), atom transfer radical polymerization (ATRP), or the like. Unlike controlled free radical polymerization, conventional free radical polymerization often proceeds at a relatively uncontrolled rate until exhaustion of monomer reactant(s). Average molecular weight could be generally controlled by controlling initiator loading, monomer loading, initiation rate, termination rate, and propagation rate; however, due to the difficulty of controlling precisely when the chain-terminating reaction might occur on any individual macroradical chain, as well as the reactivity ratio of each monomers, conventional free radical polymerization could result in a wide range of polymer chain lengths in the population of polymer molecules, as well as nonuniform composition distribution across different polymer chains, resulting in a highly polydisperse and or non-uniform copolymer. Controlled free radical polymerization occurs when the side reactions that lead to termination of the polymer chain are eliminated or significantly reduced, and the degree of polymerization is manipulated by controlling the equilibrium of a reversible transformation of the living polymer chain between an active form macroradical that will propagate chain growth and an inactive or dormant macromolecule that cannot propagate chain growth unless it is converted into the active macroradical form. Controlled free radical polymerization is thus able to produce block copolymers through free radical chain extension where molecular weight is readily controlled and with improved lower polydispersities.

Typically, the polymerization may use chain transfer agents (CTAs) including thiocarbonylthio compounds, such as dithioesters, thiocarbamates, xanthates, or the like, to mediate the polymerization via a reversible chain-transfer process. For example, the block copolymer may be produced by reacting the selected monomer(s) with a dithioester chain transfer agent and an initiator to produce the block copolymer. In some embodiments, the initiator may be light.

Exemplary chain transfer agents (CTAs) for controlled free radical polymerization include thiocarbonylthio compounds, such as 2-cyano-2-propyl benzodithioate, 4-cyano-4-(phenylcarbonothioylthio) pentanoic acid, 2-cyano-2-propyl dodecyl trithiocarbonate, 4-cyano-4-[(dodecylsulfanylthiocarbonyl)sulfanyl]pentanoic acid, 2-(dodecylthiocarbonothioylthio)-2-methylpropionic acid, cyanomethyl dodecyl trithiocarbonate, cyanomethyl methyl(phenyl)carbamodithioate, bis(thiobenzoyl)disulfide, bis(dodecylsulfanyl-thiocarbonyl)disulfide, or the like.

Examples of initiators include azobis(isobutyronitrile) (AIBN), azobis(2-methylbutyronitrile), azobis(2,4-dimethylvaleronitrile), azobis(4-cyanovaleric acid). Examples of peroxide and peroxy initiators include hydrogen peroxide, sodium peroxide, potassium peroxide, t-butyl hydroperoxide, cumene hydroperoxide, dilauroyl peroxide, tert-butyl peroxyneodecanoate, dibenzoyl peroxide, cumyl peroxide, tert-butyl peroxy-2-ethyl hexanoate, tert-butyl peroxy diethyl acetate and tert-butyl peroxy benzoate. Examples of additional initiators include ammonium and/or alkali metal persulfates, sodium perborate, perphosphoric acid and salts thereof, potassium permanganate, and ammonium or alkali metal salts of peroxydisulfuric acid, examples being alkali metal or ammonium peroxydisulfates, diacetyl peroxide, dibenzoyl peroxide, succinyl peroxide, di-tert-butyl peroxide, tert-butyl perbenzoate, tert-butyl perpivalate, tort-butyl peroxy-2-ethylhexanoate, tert-butyl permaleinate, cumene hydroperoxide, diisopropyl peroxydicarbamate, bis(o-toluoyl)peroxide, didecanoyl peroxide, dioctanoyl peroxide, dilauroyl peroxide, tert-butyl perisobutyrate, tert-butyl peracetate, di-tert-amyl peroxide, tert-butyl hydroperoxide, azobisisobutyronitrile, 2,2′-azobis(2-amidino-propane)dihydrochloride or 2,2′-azobis(2-methylbutyronitrile). Also suitable are mixtures of these initiators. As initiators it is also possible to use reduction/oxidation (i.e., redox) initiator systems. The redox initiator systems are composed of at least one, usually inorganic, reducing agent and one organic or inorganic oxidizing agent. The oxidizing component comprises, for example, the polymerization initiators already specified above. The reducing component comprises, for example, alkali metal salts of sulfurous acid, such as sodium sulfite, sodium hydrogen sulfite, alkali metal salts of disulfurous acid such as sodium disulfite, bisulfite addition compounds of aliphatic aldehydes and ketones, such as acetone bisulfite or reducing agents such as hydroxymethanesulfinic acid and salts thereof, or ascorbic acid. The redox initiator systems can be used along with soluble metal compounds whose metallic component is able to occur in a plurality of valence states. Typical redox initiator systems are, for example, ascorbic acid/iron(II)sulfate/sodium peroxodisulfate, tert-butyl hydroperoxide/sodium disulfite, tert-butyl hydroperoxide/Na hydroxymethanesulfinate. The individual components, the reducing component for example, may also be mixtures, an example being a mixture of the sodium salt of hydroxymethanesulfinic acid and sodium disulfite.

Nitroxide mediated polymerization, or NMP, which uses stable nitroxide radicals or alkoxyamines as initiators, can also be used to prepare the block copolymers. Examples of suitable initiators for NMP include N-tert-butyl-N-(2-methyl-1-phenylpropyl)-O-(1-phenylethyl) hydroxylamine, N-tert-butyl-O-[1-[4-(chloromethyl)phenyl]ethyl]-N-(2-methyl-1-phenylpropyl)hydroxylamine, 2,2,5-trimethyl-4-phenyl-3-azahexane-3-nitroxide, 2,2,6,6-tetramethyl-1-piperidinyloxy (TEMPO), or the like.

The block copolymers can also be prepared using atom transfer radical polymerization, or ATRP. Suitable initiators for ATRP include tert-butyl α-bromoisobutyrate, α-bromoisobutyryl bromide, dodecyl 2-bromoisobutyrate, ethyl α-bromoisobutyrate, methyl α-bromoisobutyrate, octadecyl 2-bromoisobutyrate, or the like. Suitable catalysis for ATRP include copper(I) chloride, copper(II) chloride, copper(I) bromide, copper(II) bromide, copper(I) iodide, and the like. Suitable ligands for ATRP include tris(2-pyridylmethyl)amine, tris[2-(dimethylamino)ethyl]amine, 4,4′-dinonyl-2,2′-dipyridyl, N,N,N′,N″,N″-pentamethyldiethylenetriamine, or the like.

The initiator may be used in molar ratio from 0.05 to 2 with respect to the chain transfer agent. In an exemplary embodiment, the initiator may be used in molar ratio from 0.07 to 1 with respect to the chain transfer agent.

The amount of initiator is generally at least 0.01 or 0.05 or 0.01 wt % to 10, or 5 or 3 wt % based on all of the monomers to be polymerized.

The polymerization reactions used to prepare the block copolymers may be performed in any suitable solvent, although the polymerization may also proceed in the absence of a solvent. Exemplary polymerization solvents include ethers, cyclic ethers, C₅₋₁₀ alkanes, C₅₋₈ cycloalkanes which may be substituted with from 1 to 3 C₁₋₄ alkyl groups, aromatic hydrocarbon solvents, halogenated hydrocarbon solvents, acetonitrile, dimethylformamide, ethylene carbonate, tetrahydrofuran (THF), propylene carbonate, dimethylsulfoxide, dimethylsulfone, water, mixtures of such solvents, supercritical solvents (such as CO₂, C₁₋₄ alkanes in which any H may be replaced with F, or the like), or a combination thereof.

Typically, the block copolymer is prepared from a central monomer that is a difunctional CTA or initiator compound that includes one or more acid-cleavable groups therein. The CTA and initiator compounds may be prepared by reacting the appropriate functionalized polymerization CTA or initiator compound with a reactive compound, such as a divinyl ether compound. The resulting compound may be a difunctional central monomer that is reactive as described herein.

In an embodiment, an initiator compound may include one or more acid-cleavable groups in its chain. In this embodiment, a diacid initiator is coupled with a tertiary alcohol or a divinyl ether to provide a polymeric initiator having acid cleavable functional groups (tertiary ester or acetal esters). Heating this initiator compound in presence of a mixture of monomers (e.g., (meth)acrylates, vinyl compounds, depicted as including functional groups R₁, R₂, and R₃ for the purposes of illustration and differentiation) will result in the incorporation of the acid cleavable functionalities into the polymer main chain as demonstrated by Scheme 1:

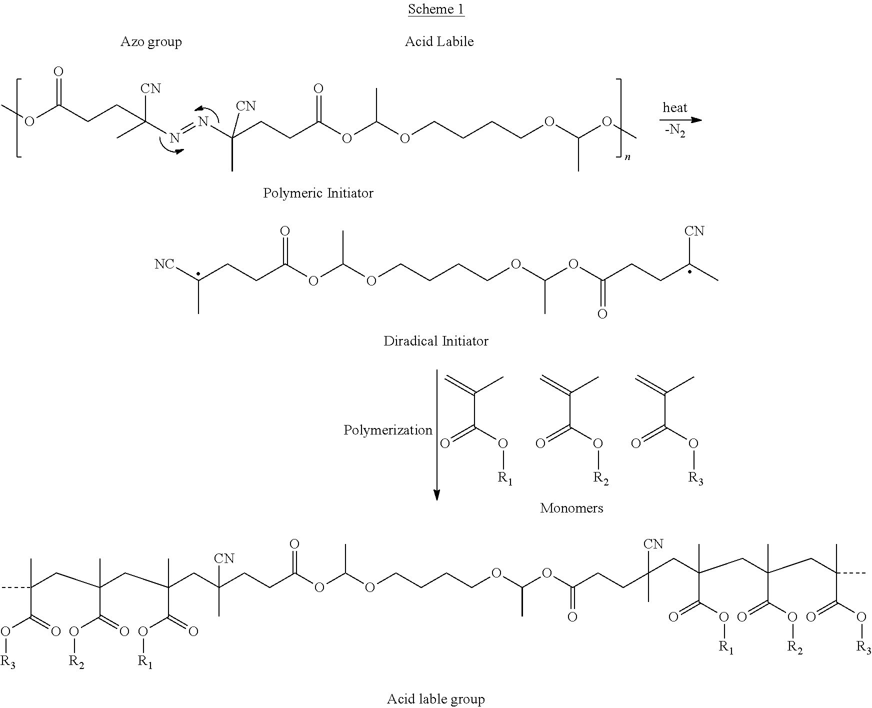

In another embodiment, a CTA compound may include one or more acid-cleavable groups in its chain. This embodiment uses an opportunely functionalized CTA (e.g., for RAFT, ATRP, or NMP mediated polymerizations) which will transfer the acid cleavable unit to the polymer main chain. A representative scheme of the process is reported in Scheme 2, where the “polymer” refers to a sequence of repeating units that represent the copolymer arms:

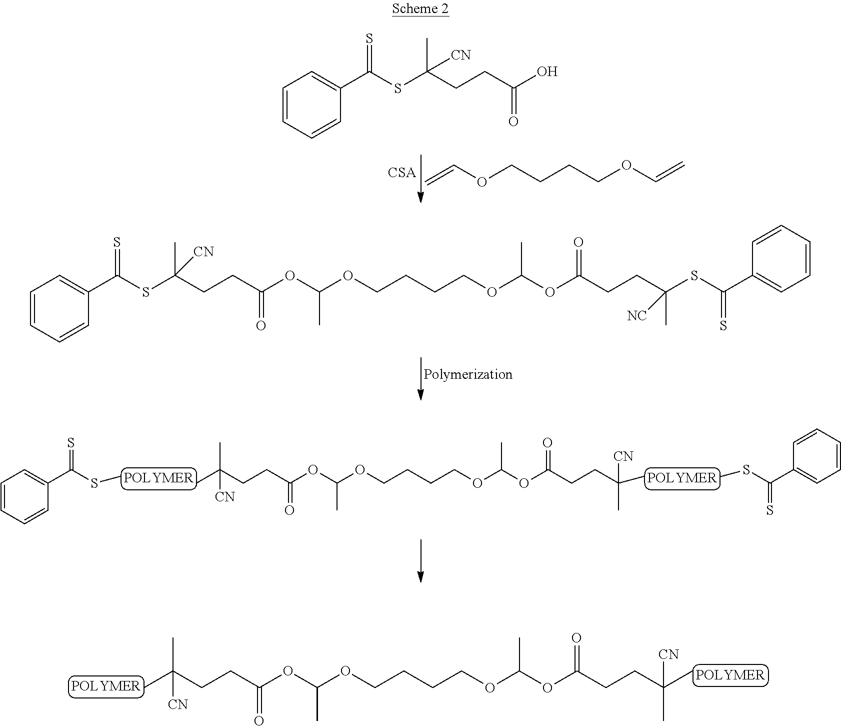

A typical procedure to prepare the block copolymers is as follows. The block copolymer may be prepared by living or controlled free radical polymerization, wherein a difunctional precursor of the center block is reacted with a first monomer to provide the first repeating unit and with a second monomer to provide the second repeating unit. A mixture of monomers is typically prepared in a solvent and combined with a difunctionalized CTA or initiator. The solution may be degassed with nitrogen and taken into a syringe as a feed mixture. The polymerization may be allowed to proceed for a period of time to form the block copolymer.

When the copolymer arms are formed as block copolymers themselves, polymerization may be conducted as follows. First, a first portion of the monomer feed mixture may be added to difunctional center block precursor to form the first blocks of the copolymer arms. Subsequently, a second portion of the monomer feed mixture may be added to the heated reaction vessel and the polymerization may be allowed to proceed for a period of time to form a second block of the copolymer arms. Additional blocks of the copolymer arms may be formed using a similar sequence of steps. Although the example described above provides for a single feed mixture, wherein the ratio of monomers remains constant for each subsequently formed block of the block copolymer, in other embodiments a different feed mixture may be added at each step to vary the ratio of the monomers used to prepare each block of the copolymer arms. For block copolymers that include additional copolymer arm block beyond the first block and the second block as described herein, different feed mixtures may be used to form the third block and subsequent blocks, such that each block of the copolymer arms may have the same or different monomer compositions and/or ratios.

After the polymerization is complete, the formed block copolymer is isolated. The isolating step may be conducted by known procedures, and may include evaporating any residual monomer and/or solvent, precipitating in a suitable solvent, filtering or centrifuging the precipitated block copolymer, washing the block copolymer, and/or drying the washed block copolymer. Metal compounds may be removed by passing through a column or a pad of alumina, silica, and/or clay. Alternatively, metal compounds may be oxidized (if necessary) and retained in the block copolymer as a stabilizer. The chain terminating groups, when present, may be cleaved from the block copolymers using any suitable methods known in the art.

Precipitation can be typically conducted using a suitable C₅₋₈ alkane or C₅₋₈ cycloalkane solvent, such as pentane, hexane, heptane, cyclohexane, or mineral spirits, or using a C₁₋₆ alcohol, such as methanol, ethanol, or isopropanol, water, or a combination of suitable solvents.

Also provided is a photoresist composition including the block copolymer as described herein, and a solvent. In some embodiments, the photoresist composition may include the block copolymer as described herein, a photoacid generator, and a solvent. In still other embodiments, the photoresist composition may include a first polymer that is the block copolymer as described herein, a photoacid generator, and a solvent, and may further include a second (different) polymer that is structurally different from the first polymer (the block copolymer).

The second polymer may include one or more polymerized (e.g., repeating) units, such as those described herein for the copolymer arms. Exemplary second polymer may be polyacrylates, polyvinylethers, polyesters, polynorbornenes, polyacetals, polyethylene glycols, polyamides, polyacrylamides, polyphenols, novolacs, styrenic polymers, polyvinyl alcohols, or a combination thereof. For example, the second polymer may include a repeating unit that includes an acid labile group, a hydroxyaryl group, a fluoroalcohol group, a sulfonamide group, a lactone group, or a combination thereof.

The second polymer typically has a M_{w} from 1,000 to 50,000 g/mol, specifically from 2,000 to 30,000 g/mol, more specifically from 3,000 to 20,000 g/mol, still more specifically from 3,000 to 10,000 g/mol. The PDI of the polymer, which is the ratio of M_{w} to Mₙ is typically from 1.1 to 3, and specifically from 1.1 to 2. Molecular weights are determined by GPC using polystyrene standards.

The second polymer may be prepared using any suitable methods in the art. For example, one or more monomers corresponding to the polymerized units described herein may be combined, or fed separately, using suitable solvent(s) and initiator, and polymerized in a reactor. For example, the second polymer may be obtained by polymerization of the respective monomers under any suitable conditions, such as by heating at an effective temperature, irradiation with actinic radiation at an effective wavelength, or a combination thereof.

The photoresist composition includes a solvent for dissolving the components of the composition and facilitating its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol and 4-methyl-2-pentanol; propylene glycol monomethyl ether (PGME), ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents are PGME, PGMEA, EL, GBL, HBM, CHO, and combinations thereof. The total solvent content (i.e., cumulative solvent content for all solvents) in the photoresist composition is typically from 40 to 99 weight percent (wt %), more typically from 70 to 99 wt %, and still more typically from 85 to 99 wt %, based on total weight of the photoresist composition. The desired solvent content will depend, for example, on the desired thickness of the coated photoresist layer and coating conditions.

In the photoresist compositions, the block copolymer typically may be present in the photoresist composition in an amount from 10 to 99.9 wt %, typically from 25 to 99 wt %, and more typically from 50 to 95 wt %, based on total solids of the photoresist composition. It will be understood that total solids includes the block copolymer, PAG(s), and other non-solvent components.

The photoresist composition may further include a photoacid generator (PAG). The PAG may be in ionic or non-ionic form. The PAG may be in polymeric or non-polymeric form. In polymeric form, the PAG may be present as a moiety in a repeating unit of a polymer that is derived from a polymerizable PAG monomer. In some embodiments, the block copolymer may further include a repeating unit that includes a PAG functionality (e.g., as a salt group of a repeating unit).

Suitable PAG compounds may be of the formula G⁺A⁻, wherein G⁺ is a photoactive cation and A⁻ is an anion that can generate a photoacid. The PAG cation is preferably chosen from onium cations, preferably iodonium or sulfonium cations. Particularly suitable anions include those whose conjugated acids have a pKa from −15 to 10. The PAG anion is typically an organic anion having a sulfonate group or a non-sulfonate-type group, such as sulfonamidate, sulfonimidate, methide, or borate.

In some embodiments, the PAG cation may be a sulfonium cation or an iodonium cation. For example, the PAG cation may be a sulfonium cation of Formula (14) or an iodonium cation of Formula (15):

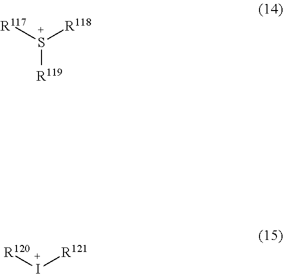

In Formulae (14) and (15), R¹¹⁷ to R¹²¹ may each independently be substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₆₋₃₀ iodoaryl, substituted or unsubstituted C₃₋₃₀ heteroaryl, substituted or unsubstituted C₇₋₂₀ arylalkyl, or substituted or unsubstituted C₄₋₂₀ heteroarylalkyl, or combinations thereof. Each of R¹¹⁷ to R¹¹⁹ may be either separate or connected to another group of R¹¹⁷ to R¹¹⁹ via a single bond or a divalent linking group to form a ring. R¹²⁰ and R¹²¹ may be either separate or connected to each other via a single bond or a divalent linking group to form a ring. Each of R¹¹⁷ to R¹²¹ optionally may include as part of its structure a divalent linking group. Each of R¹¹⁷ to R¹²¹ independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups.

Exemplary sulfonium cations of Formula (14) may include one or more of the following:

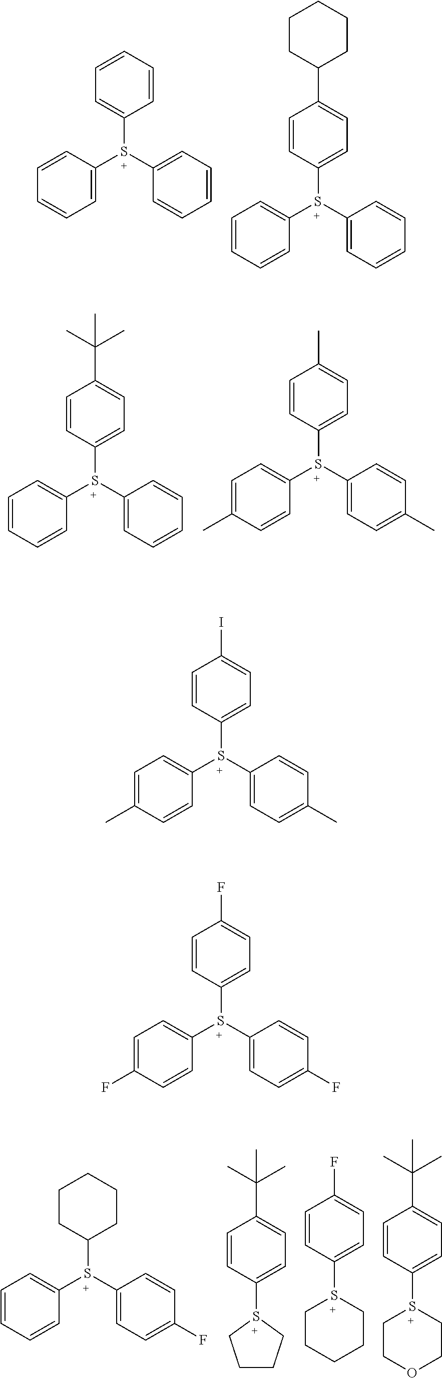

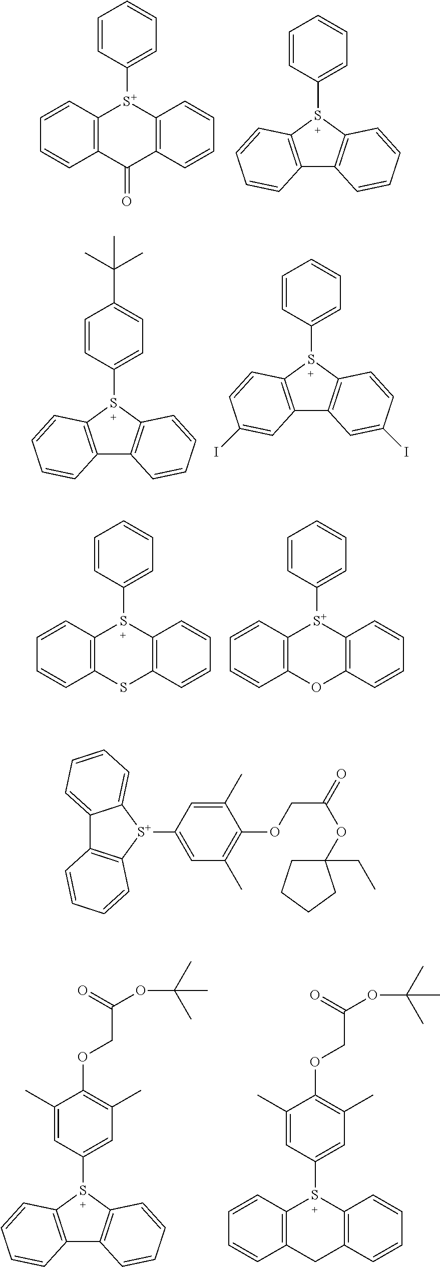

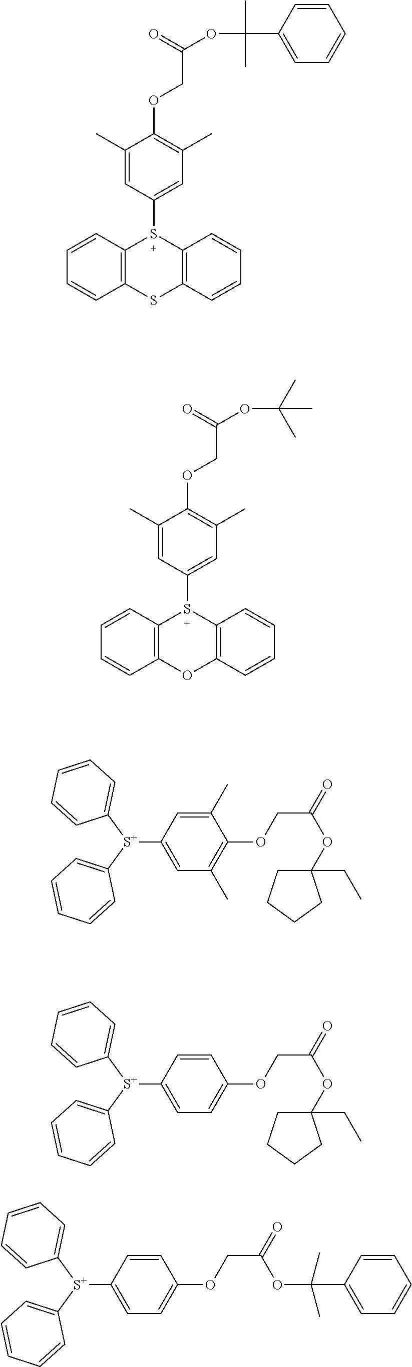

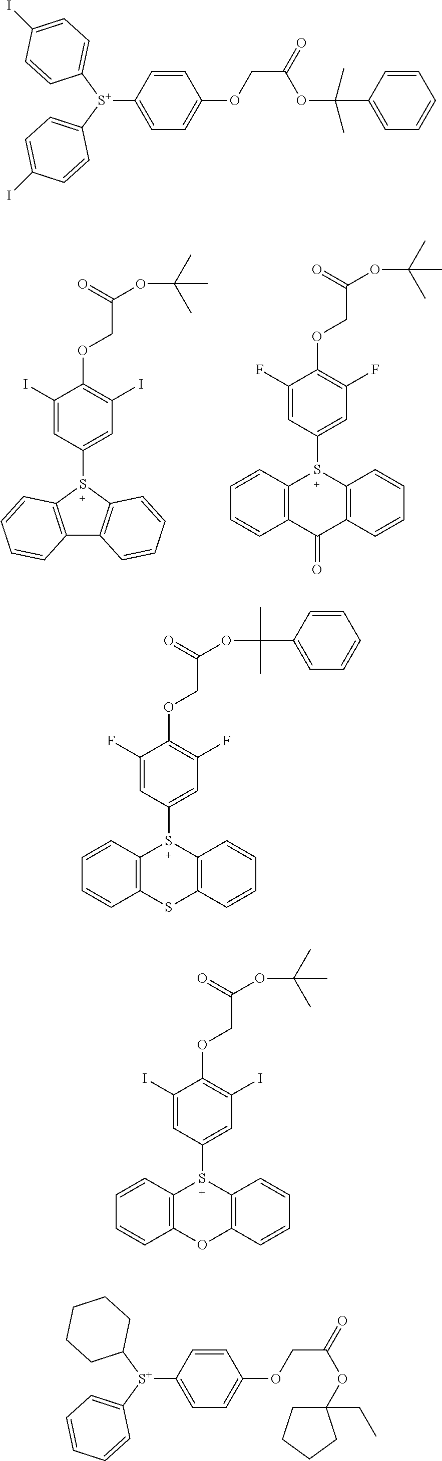

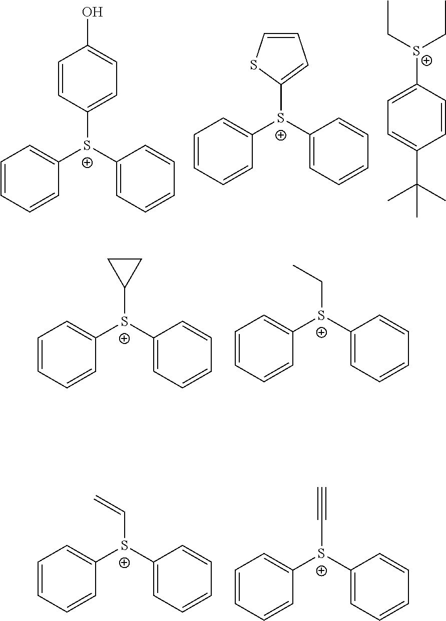

Exemplary iodonium cations of Formula (15) may include one or more of the following:

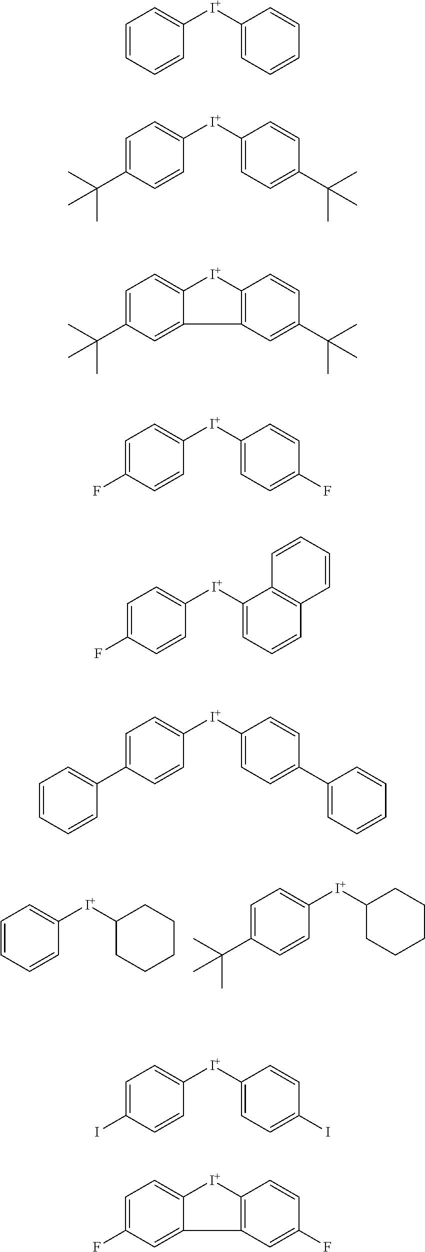

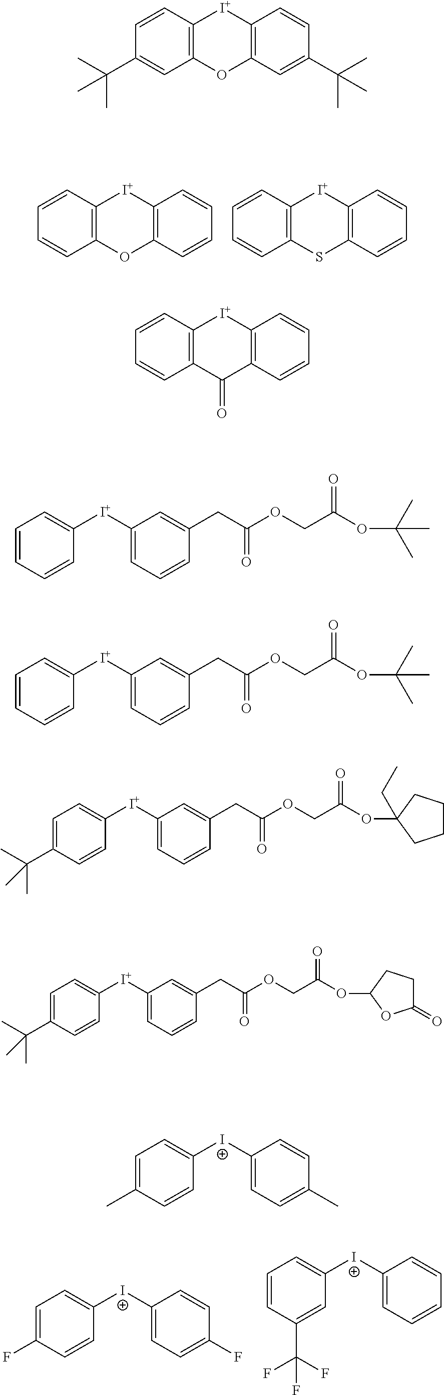

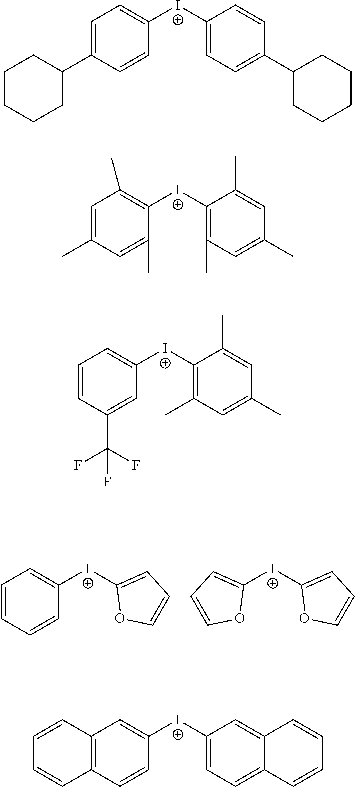

Exemplary organic anions having a sulfonate group may include one or more of the following:

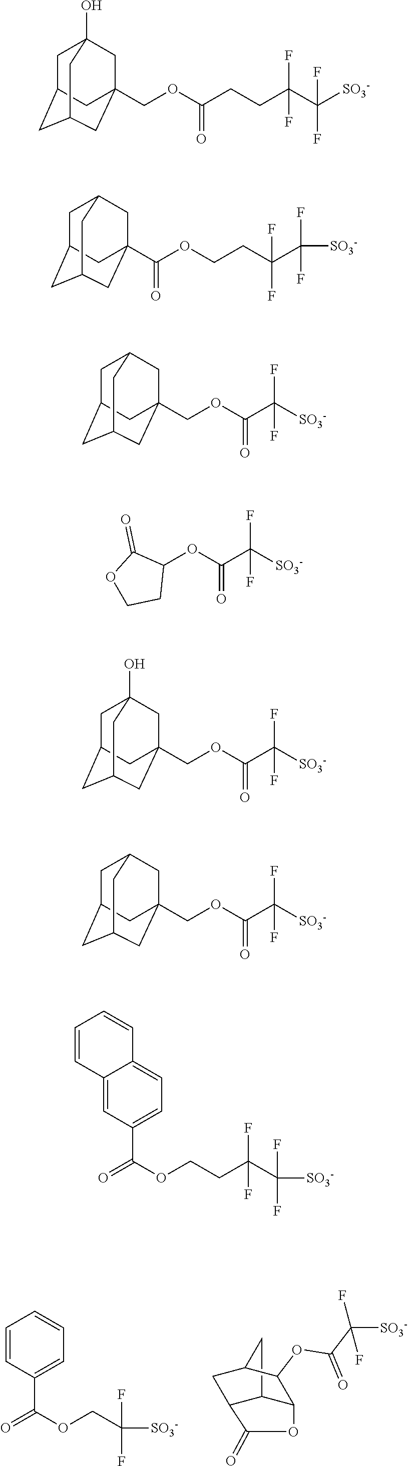

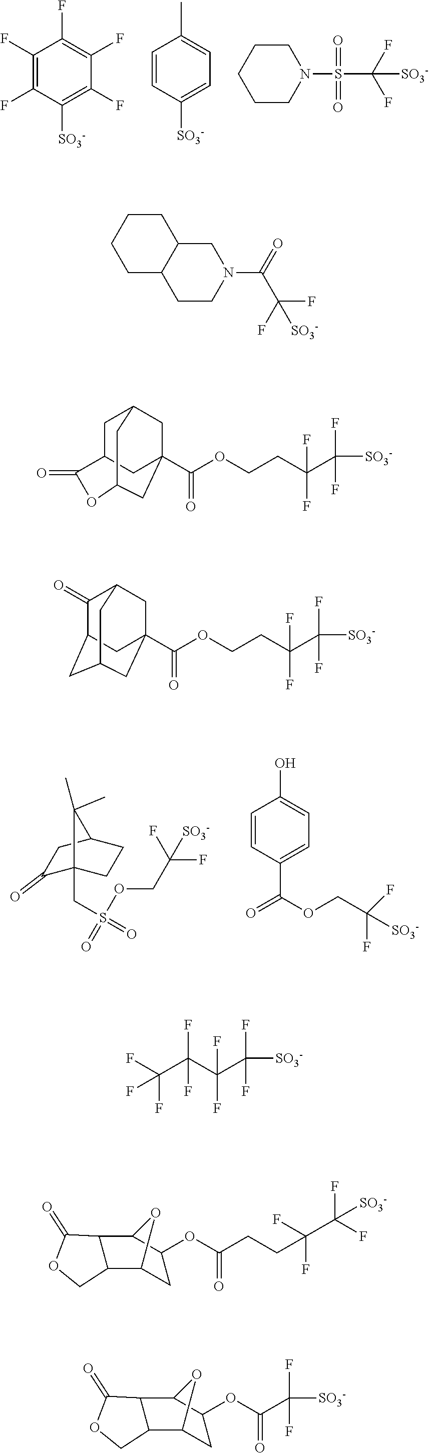

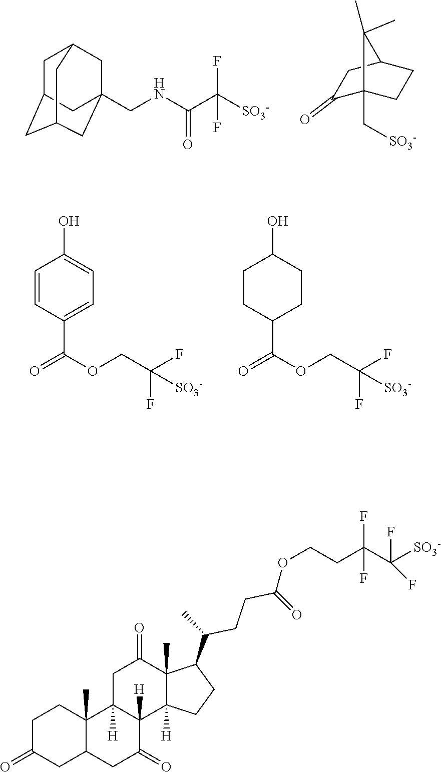

Exemplary non-sulfonated anions may include one or more of the following:

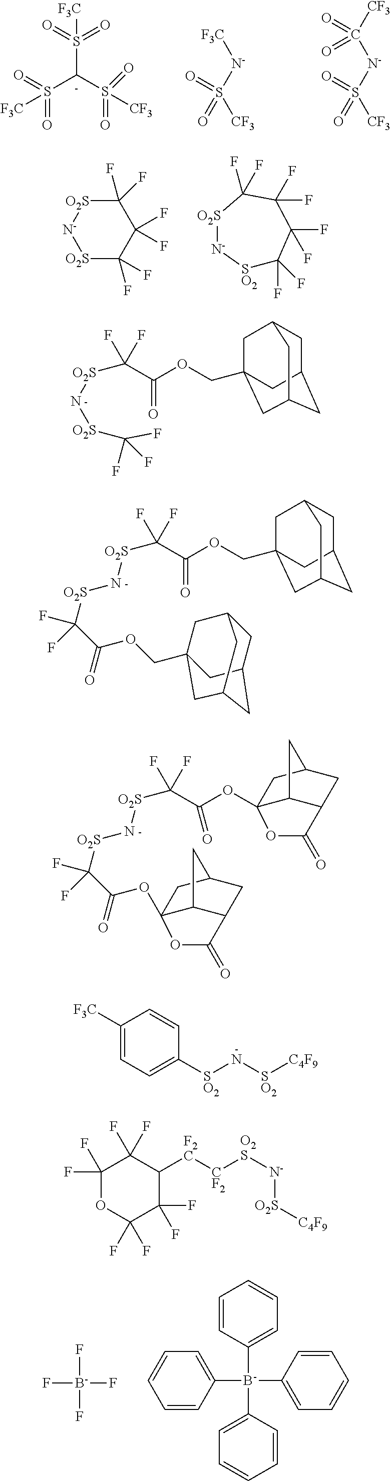

Commonly used onium salts may include, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Other useful PAG compounds are known in the art of chemically amplified photoresists and include, for example: non-ionic sulfonyl compounds, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable photoacid generators are further described in U.S. Pat. Nos. 8,431,325 and 4,189,323.

Typically, when the photoresist composition includes a non-polymeric PAG, the PAG is present in the photoresist composition in an amount from 0.1 to 55 wt %, more typically from 1 to 25 wt %, based on total solids of the photoresist composition. When present in polymeric form, the PAG is typically included in a polymer in an amount from 1 to 25 mol %, more typically from 1 to 20 mol %, or from 2 to 10 mol %, based on total polymerized units in the polymer.

In some aspects, the anion and/or cation of the PAG does not include and is free of —F, —CF₃, or —CF₂— groups. It should be understood that “free of —F, —CF₃, or —CF₂— groups” means that the anion and/or cation of the PAG excludes groups such as —CH₂CF₃ and —CH₂CF₂CH₃. In still other aspects, the anion and/or the cation of the PAG is free of fluorine (i.e., does not contain a fluorine atom and is not substituted by a fluorine-containing group). In some aspects, the photoacid generator is free of fluorine (i.e., both the photoactive cation and the anion are free of fluorine).

In some aspects, the photoresist composition may further include a surface-active material. Preferably, the surface-active material is hydrophobic, and is substantially not miscible with and has a lower surface energy than the block copolymer and other solid components of the photoresist composition. When coated on a substrate, the surface-active material can thereby segregate from other solid components of the photoresist composition to a top surface of the formed photoresist layer. The surface-active material can provide beneficial surface properties to the photoresist composition when coated on a substrate. For example, in an immersion exposure process, the surface-active material can function as a barrier layer between the immersion fluid, typically water, which is interposed between the lens of the exposure tool and the photoresist layer. This can minimize or prevent leaching of components of the underlying portion of the photoresist into the immersion fluid that could otherwise cause contamination of the lens and alter the effective refractive index and transmission properties of the immersion fluid. Due to its hydrophobic nature, the surface-active material can allow for a high receding contact angle with respect to the immersion fluid, which can allow for faster scanning speeds and increased process throughput. In immersion and non-immersion exposure processes, the surface-active material can also have a beneficial impact on reducing defectivity, for example, patterning defects such as closed contacts and bridging defects in line-space patterns.

The surface-active material is preferably soluble in the developer or becomes soluble in the developer during patterning such as by interaction with a generated photoacid or with the developer. In some aspects, the surface-active material may be a polymeric material. The surface-active material can be a homopolymer or a copolymer comprising two, three, or more different types of repeat units. In some aspects, the surface-acting material may be non-polymeric, in the form of a single molecule. Suitable for the surface-active materials include, for example, one or more groups chosen from acid groups such as carboxylic acid or sulfonic acid groups, acid-labile groups, base-labile groups, base-soluble groups such as fluoroalcohol or phenol groups, alkyl groups, fluoroalkyl groups, ester groups, and combinations thereof. In the case of an aqueous base developer such as a 0.26 normal (N) aqueous solution of tetramethylammonium hydroxide (TMAH), the surface-active polymer preferably includes one or more base-labile or base soluble groups to enhance the solubility in the developer solution after exposure to activating radiation and post-exposure baking.

When present, the surface-active material is typically present in the photoresist compositions in an amount from 0.01 to 10 wt %, typically from 1 to 5 wt %, based on total solids of the photoresist composition.

The photoresist composition may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the photoresist compositions in an amount from 0.01 to 10 wt %, based on total solids of the photoresist composition.

PDQs generate a weak acid upon irradiation. The acid generated from a photo-decomposable quencher is not strong enough to react rapidly with acid-labile groups that are present in the resist matrix. Exemplary photo-decomposable quenchers include, for example, photo-decomposable cations, and preferably those also useful for preparing strong acid generator compounds, paired with an anion of a weak acid (pKa>1) such as, for example, an anion of a C₁₋₂₀ carboxylic acid or C₁₋₂₀ sulfonic acid. Exemplary carboxylic acids include formic acid, acetic acid, propionic acid, tartaric acid, succinic acid, cyclohexanecarboxylic acid, benzoic acid, salicylic acid, and the like. Exemplary sulfonic acids include p-toluene sulfonic acid, camphor sulfonic acid and the like. In a preferred embodiment, the photo-decomposable quencher is a photo-decomposable organic zwitterion compound such as diphenyliodonium-2-carboxylate.

The PDQ may be in non-polymeric or polymer-bound form. The polymerized units containing the photo-decomposable quencher are typically present in an amount from 0.1 to 30 mol %, preferably from 1 to 10 mol % and more preferably from 1 to 2 mol %, based on total repeating units of the polymer.

Exemplary basic quenchers include, for example, linear aliphatic amines such as tributylamine, trioctylamine, triisopropanolamine, tetrakis(2-hydroxypropyl)ethylenediamine n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher may be present in repeating units of the polymer. The repeating units containing the quencher are typically present in an amount from 0.1 to 30 mol %, preferably from 1 to 10 mol % and more preferably from 1 to 2 mol %, based on total repeating units of the polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants (3M Corporation); and fluorodiols such as POLYFOX™ PF-636, PF-6320, PF-656, and PF-6520 fluorosurfactants (Omnova). In an aspect, the photoresist composition further includes a surfactant polymer including a fluorine-containing repeating unit.

Also provided are methods of forming a pattern. According to an aspect, a method of forming a pattern includes applying a layer of a photoresist composition on a substrate to form a photoresist composition layer; pattern-wise exposing the photoresist composition layer to activating radiation to form an exposed photoresist composition layer; and developing the exposed photoresist composition layer to provide a resist relief image. The photoresist composition includes the block copolymer as described herein and a solvent.

In some embodiments, the method includes cleaving the acid-labile group in the backbone of the block copolymer. In some embodiments, the pattern-wise exposing the photoresist composition cleaves the acid-labile group in the backbone of the block copolymer. For example, the pattern-wise exposing the photoresist composition may cleave one or more of the acid-labile groups that are present in the backbone of the block copolymer via an acid that is generated from a photoacid generator. In some embodiments, the photoresist composition may cleave one or more of the acid-labile groups that are present in the backbone of the block copolymer via an acid that is generated from a thermal acid generator.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP™ 3000, AP™ 8000, and AP™ 9000S designations, available from DuPont Electronics & Industrial (Marlborough, Massachusetts).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, from 1,000 to 2,500 rpm, for a period from 15 to 120 seconds to obtain a layer of the photoresist composition on the substrate. It will be appreciated by those skilled in the art that the thickness of the coated layer may be adjusted by changing the spin speed and/or the total solids of the composition. A photoresist composition layer formed from the compositions of the invention typically has a dried layer thickness from 20 nanometers (nm) to 1 micrometer (Qim), preferably from greater than 20 nm to 500 nm, and more preferably from 20 nm to 200 nm.

The photoresist composition is typically next soft-baked to minimize the solvent content in the layer, thereby forming a tack-free coating and improving adhesion of the layer to the substrate. The soft bake is performed, for example, on a hotplate or in an oven, with a hotplate being typical. The soft bake temperature and time will depend, for example, on the photoresist composition and thickness. The soft bake temperature is typically from 80 to 170° C., and more typically from 90 to 150° C. The soft bake time is typically from 10 seconds to 20 minutes (mins.), more typically from 1 to 10 mins., and still more typically from 1 to 2 mins. The heating time can be readily determined by one of ordinary skill in the art based on the components of the composition.

The photoresist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nanometer (nm), sub-300 nm or sub-200 nm, with 248 nm (KrF), 193 nm (ArF), 13.5 nm (EUV) wavelengths or e-beam lithography being preferred. Preferably, the activating radiation is 193 nm radiation or EUV wavelengths. The methods find use in immersion or dry (non-immersion) lithography techniques. The exposure energy is typically from 1 to 200 millijoules per square centimeter (mJ/cm²), preferably from 10 to 100 mJ/cm² and more preferably from 20 to 50 mJ/cm², dependent upon the exposure tool and components of the photoresist composition.

Following exposure of the photoresist layer, a post-exposure bake (PEB) of the exposed photoresist layer is performed. The PEB can be conducted, for example, on a hotplate or in an oven, with a hotplate being typical. Conditions for the PEB will depend, for example, on the photoresist composition and layer thickness. The PEB is typically conducted at a temperature from 70 to 150° C., preferably from 75 to 120° C., and a time from 30 to 120 seconds. A latent image defined by the polarity-switched (exposed regions) and unswitched regions (unexposed regions) is formed in the photoresist.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time from 5 to 60 seconds being typical. Development is typically conducted at room temperature.

Suitable developers for a PTD process include aqueous base developers, for example, quaternary ammonium hydroxide solutions such as TMAH, preferably 0.26 N TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 98 wt % or more, or 100 wt %, based on total weight of the developer. Suitable organic solvents for the NTD developer include, for example, those chosen from ketones, esters, ethers, alcohols, hydrocarbons, and mixtures thereof. The developer is typically 2-heptanone or n-butyl acetate.

A coated substrate may be formed from the photoresist compositions of the invention. Such a coated substrate includes: (a) a substrate having one or more layers to be patterned on a surface thereof, and (b) a layer of the photoresist composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following non-limiting examples.

### EXAMPLES

### Synthesis Examples

The synthetic reactions were performed under a nitrogen atmosphere. Dimethyl 2,2′-azobis(2-methylpropionate) (V601) and 1,1′-azobis(cyclohexane-1-carbonitrile) (V40) initiators were purchased from Wako Specialty Chemicals. Diphenyliodonium-2-carboxylate monohydrate (DPIC), diphenyl(p-phenyl)sulfonium 2-(((3r,5r,7r)-adamantane-1-carbonyl)oxy)-1,1-difluoroethane-1-sulfonate (TDPS IAD), ethylcyclopentyl methacrylate (M1), γ-butyrolacton-2-yl methacrylate (M2), 2-oxohexahydro-2H-3,5-methanocyclopenta[b]furan-6-yl methacrylate (M3), ethyl lactate (EL), gamma-butyrolactone (GBL), tetrahydrofuran (THF), 4-cyano-4-((phenylcarbonothioyl)thio)-pentanoic acid, and 1,4-bis((vinyloxy)methyl)cyclohexane were purchased from commercial sources and used without further purification.

### Synthesis of RAFT Crosslinker C1

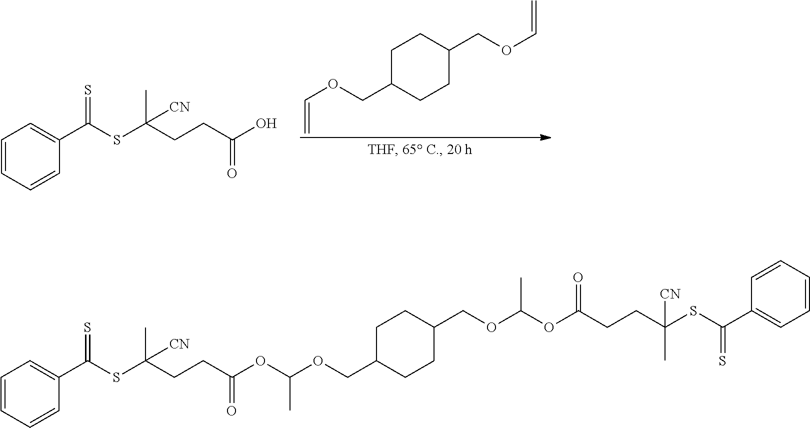

0.18 milliliters (mL) of 1,4-bis(vinyloxymethyl)cyclohexane (0.15 grams (g), 0.764 millimoles (mmol)) and 0.427 g of 4-cyano-4-((thiobenzyl)sulfonyl)-pentanoic acid (1.53 mmol) were transferred into a 20 mL scintillation vial and reacted at 65° C. for 20 hours. Subsequently, the reaction was allowed to cool to room temperature, and 10 mL of dry THF was added thereto and the solution was passed through a basic alumina column to remove the excess of 4-cyano-4-((thiobenzyl)sulfonyl)pentanoic acid. Finally, the THF was removed using a rotary evaporator, and the desired bifunctional crosslinker C1 was isolated as a red oil at a 67% yield. The structure of C1 was confirmed using ¹H spectroscopy. ¹H NMR (500 MHz, CDCl₃, 6, ppm): 7.84 (d, 4H), 7.47 (t, 2H), 7.29 (t, 4H), 5.90 (m, 2H), 3.67 (m, 4H), 2.65-2.53 (m, 8H), 1.87 (s, 6H), 1.38-1.62 (m, 14H).

### Synthesis of RAFT Block Copolymer P1

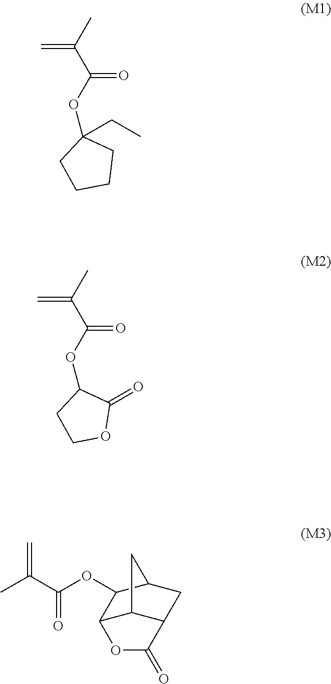 [SMILES: C=C(C)C(=O)OC1(CC)CCCC1 ; C=C(C)C(=O)OC1CCOC1=O ; C=C(C)C(=O)OC1C2CC3C(=O)OC1C3C2]

A two neck 100 mL round bottom flask was charged with the monomers (M1 (2.9 g, 16.0 mmol), M2 (5.0 g, 29.4 mmol), and M3 (1.78 g, 8.0 mmol)), and dry THF (about 33 wt % solution). Then, V-65 (27 mg, 0.11 mmol) and RAFT crosslinker C1 (0.4 g, 0.53 mmol) were dissolved in THF (2 ml) and added into the above solution. The mixture was deoxygenated by purging under nitrogen for 30 minutes with stirring. The reaction mixture was then warmed to 60° C. and left stirring (400 rpm) for 8 hours under nitrogen. The heating was stopped, the reaction mixture was opened to the ambient atmosphere, and the reaction mixture was then cooled with dry ice. The reaction mixture was combined with 10 mL of dry THF, and then precipitated into 500 mL of methanol (MeOH) as a pink solid. The solids were collected by filtration and dried overnight in a vacuum oven, giving a red solid. Yield: 82%. MW=14.2 kDa, PDI=1.32, as determined by gel permeation chromatography (GPC) using polystyrene standards. The molar ratio of the repeating units M1/M2/M3 was determined by ¹³C-NMR to be 30:55:15.

### Synthesis of Comparative Copolymer PC1

A one-neck 100 mL round bottom flask was charged with M1 (7.9 g, 43.3 mmol), M2 (13.52 g, 79.5 mmol), M3 (4.82 g, 21.7 mmol), and EL/GBL (30% wt solution, 1:1). The contents were stirred for 15 minutes and then dimethyl 2,2′-azobis(2-methylpropionate) (V601) (1.82 g, 7.9 mmol) was charged to the reaction mixture. The contents of the round bottom flask were then purged under nitrogen for 30 minutes with stirring. The reaction mixture was then heated to 80° C. with stirring for 5 hours. The reaction mixture was then allowed to cool to room temperature, and then a precipitate was formed by the addition of methanol. The solid was collected by filtration and dried in a vacuum oven to give copolymer PC1 as a white solid. Yield: 80%. MW=7.8 kDa, PDI=1.76, as determined by gel permeation chromatography (GPC) using polystyrene standards. The molar ratio of the repeating units M1/M2/M3 was determined by ¹³C-NMR to be 30:55:15.

### Lithographic Evaluation

Photoresist compositions were prepared by combining the solid components with solvents using the materials and amounts indicated in Table 1, where the amounts are expressed in wt % based on 100 wt % of total weight of the solids. The total solids content for the photoresist compositions was 3.1 wt %. The solvent system contained PGMEA (35 wt %, based on 100 wt % of the total solvent system, Si) and methyl-2-hydroxyisobutyrate (65 wt %, based on 100 wt % of the total solvent system, S2). Each mixture was shaken using a mechanical shaker and then filtered through a PTFE disk-shaped filter having a pore size of 0.2 micron.

Immersion lithography was carried out with a TEL Lithius 300 mm wafer track and ASML 1900i immersion scanner at 1.35 NA, 0.90/0.988 inner/outer sigma, and dipole illumination with 35Y polarization. Wafers for photolithographic testing were coated to a thickness of 800 Å using AR™ 40A bottom antireflective coating (BARC, DuPont Electronics & Industrial) and cured at 205° C./60 seconds. Over the BARC layer was coated a layer having a thickness of 400 Å using AR™ 104 BARC (DuPont Electronics & Industrial) and cured of 175° C./60 seconds, to form a BARC stack. Over the BARC stack was coated as layer having a thickness of 900 Å of a photoresist composition notes in Table 1 using a soft back at 90° C./60 seconds. Wafers were exposed to a pattern of 38 nm/76 nm pitch and 37 nm/74 nm pitch lines/spaces at increasing focus and increasing dose and then post-exposure baked (PEB) at 95° C./60 seconds. Following PEB, wafers were developed in 0.26 N aqueous TMAH developer for 12 seconds, rinsed with DI water, and spun dry. Metrology was performed on a Hitachi CG4000 CD-SEM to evaluate Linewidth Roughness (LWR) and sizing energy (Eₛ) and results thereof are provided in Table 1.

TABLE 1

| Example | | | | Additive | Eₛ | LWR |
|---|---|---|---|---|---|---|
| No. | Polymer | PAG | Base | polymer | (mJ/cm²) | (nm) |
| PR-1 | P1 | PAG-A | Q-1 | S | 20.9 | 4.89 |
| | (80.72) | (15.05) | (2.23) | (2) | | |
| PR-2* | PC1 | PAG-A | Q-1 | S | X | X |
| | (80.72) | (15.05) | (2.23) | (2) | | |

*Denotes a comparative photoresist composition
X: not resolved

The structures of PAG-A and Q-1 were as follows:

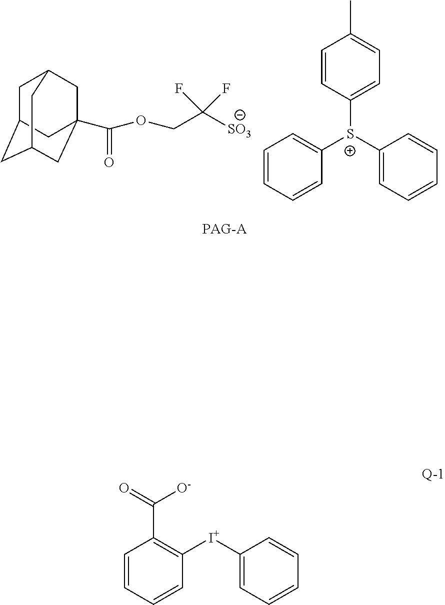

The additive polymer (S) was prepared as described in U.S. Pat. No. 11,480,878 B2 and has the structure shown below:

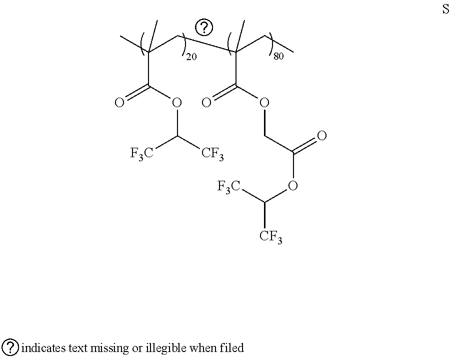

As can be seen in Table 1, the photoresist composition PR-1 achieved improved LWR compared to comparative compositions PR-2*.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A block copolymer, comprising:
a center block comprising an acid-labile group in a backbone of the block copolymer; and
at least two copolymer arms covalently attached to the center block,
wherein each copolymer arm comprises:
a first repeating unit, and
a second repeating unit that is different from the first repeating unit.

2. The block copolymer of claim 1, wherein the center block has a structure represented by Formula (1), (2), or (3): 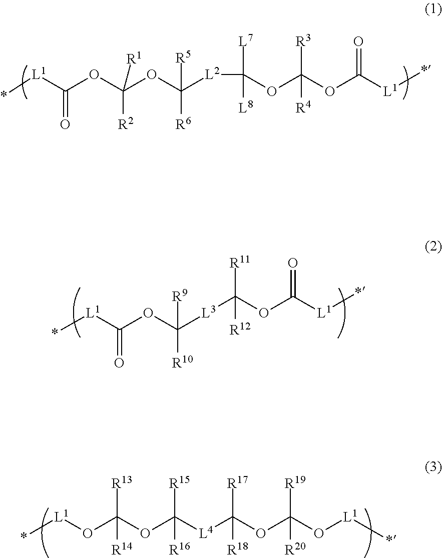
wherein, in Formulae (1), (2), and (3),
R¹ to R⁴, R¹³, R¹⁴, R¹⁹, and R²⁰ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl,
optionally, R¹ and R² together form a ring via one or more divalent linking groups, R³ and R⁴ together form a ring via one or more divalent linking groups, R¹³ and R¹⁴ together form a ring via one or more divalent linking groups, and/or R¹⁹ and R²⁰ together form a ring via one or more divalent linking groups,
R⁵ to R⁸ and R¹⁵ to R¹⁸ are each hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl,
optionally, R⁵ and R⁶ together form a ring via one or more divalent linking groups, R⁷ and R⁸ together form a ring via one or more divalent linking groups, R¹⁵ and R¹⁶ together form a ring via one or more divalent linking groups, and/or R¹⁷ and R¹⁸ together form a ring via one or more divalent linking groups,
optionally, R¹ and R⁵ together form a ring via one or more divalent linking groups, R² and R⁶ together form a ring via one or more divalent linking groups, R³ and R⁷ together form a ring via one or more divalent linking groups, R⁴ and R⁸ together form a ring via one or more divalent linking groups, R¹³ and R¹⁵ together form a ring via one or more divalent linking groups, R¹⁴ and R¹⁶ together form a ring via one or more divalent linking groups, R¹⁷ and R¹⁹ together form a ring via one or more divalent linking groups, and/or R¹⁸ and R²⁰ together form a ring via one or more divalent linking groups,
R⁹ to R¹² are each independently substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃-20 heterocycloalkenyl, substituted or unsubstituted C₆₋₂₀ aryl, or substituted or unsubstituted C₂₋₂₀ heteroaryl,
optionally, R⁹ and R¹⁰ together form a ring via one or more divalent linking groups, R¹¹ and R¹² together form a ring via one or more divalent linking groups, R⁹ and R¹¹ together form a ring via one or more divalent linking groups, and/or R¹⁰ and R¹² together form a ring via one or more divalent linking groups,
each L¹ is independently a divalent linking group comprising at least one carbon atom,
L² and L⁴ are each independently a divalent linking group,
L³ is a single bond or one or more divalent linking groups, and
* and *′ each indicates a binding site to a copolymer arm.

3. The block copolymer of claim 2, wherein L¹ does not comprise sulfur.

4. The block copolymer of claim 1, wherein the first repeating unit comprises an acid-labile group.

5. The block copolymer of claim 1, wherein the second repeating unit comprises a polar group.

6. The block copolymer of claim 1, further comprising a third repeating unit, wherein the third repeating unit is different from the first repeating unit and the second repeating unit.

7. The block copolymer of claim 1, wherein the block copolymer has a dispersity index from 1.1 to 1.4, as determined by gel permeation chromatography using polystyrene standards.

8. The block copolymer of claim 1, wherein the block copolymer is prepared by living or controlled free radical polymerization, wherein a difunctional precursor of the center block is reacted with a first monomer to provide the first repeating unit and with a second monomer to provide the second repeating unit.

9. A photoresist composition, comprising the block copolymer of claim 1 and a solvent.

10. A pattern forming method, comprising:
forming on a substrate a photoresist composition layer from the photoresist composition of claim 9;
pattern-wise exposing the photoresist composition layer to activating radiation; and
developing the exposed photoresist composition layer to provide a resist relief image.

11. The method of claim 10, further comprising cleaving the acid-labile group in the backbone of the block copolymer.

12. The photoresist composition of claim 9, wherein in the block copolymer, the center block has a structure represented by Formula (1), (2), or (3): 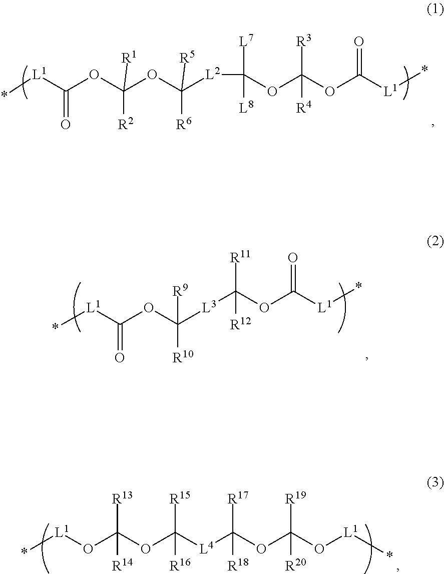
wherein, in Formulae (1), (2), and (3),
R¹ to R⁴, R¹³, R¹⁴, R¹⁹, and R²⁰ are each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl,
optionally, R¹ and R² together form a ring via one or more divalent linking groups, R³ and R⁴ together form a ring via one or more divalent linking groups, R¹³ and R¹⁴ together form a ring via one or more divalent linking groups, and/or R¹⁹ and R²⁰ together form a ring via one or more divalent linking groups,
R⁵ to R⁸ and R¹⁵ to R¹⁸ are each hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃-20 heterocycloalkenyl, substituted or unsubstituted C₆₋₂₀ aryl, or substituted or unsubstituted C₂₋₂₀ heteroaryl,
optionally, R⁵ and R⁶ together form a ring via one or more divalent linking groups, R⁷ and R⁸ together form a ring via one or more divalent linking groups, R¹⁵ and R¹⁶ together form a ring via one or more divalent linking groups, and/or R¹⁷ and R¹⁸ together form a ring via one or more divalent linking groups,
optionally, R¹ and R⁵ together form a ring via one or more divalent linking groups, R² and R⁶ together form a ring via one or more divalent linking groups, R³ and R⁷ together form a ring via one or more divalent linking groups, R⁴ and R⁸ together form a ring via one or more divalent linking groups, R¹³ and R¹⁵ together form a ring via one or more divalent linking groups, R¹⁴ and R¹⁶ together form a ring via one or more divalent linking groups, R¹⁷ and R¹⁹ together form a ring via one or more divalent linking groups, and/or R¹⁸ and R²⁰ together form a ring via one or more divalent linking groups,
R⁹ to R¹² are each independently substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃-20 heterocycloalkenyl, substituted or unsubstituted C₆₋₂₀ aryl, or substituted or unsubstituted C₂₋₂₀ heteroaryl,
optionally, R⁹ and R¹⁰ together form a ring via one or more divalent linking groups, R¹¹ and R¹² together form a ring via one or more divalent linking groups, R⁹ and R¹¹ together form a ring via one or more divalent linking groups, and/or R¹⁰ and R¹² together form a ring via one or more divalent linking groups,
each L¹ is independently a divalent linking group comprising at least one carbon atom,
L² and L⁴ are each independently a divalent linking group,
L³ is a single bond or one or more divalent linking groups, and
* and *′ each indicates a binding site to a copolymer arm.

13. The photoresist composition of claim 9, wherein in the block copolymer, L¹ does not comprise sulfur.

14. The photoresist composition of claim 9, wherein in the block copolymer, the first repeating unit comprises an acid-labile group.

15. The photoresist composition of claim 9, wherein in the block copolymer, the second repeating unit comprises a polar group.

16. The photoresist composition of claim 9, wherein in the block copolymer further comprises a third repeating unit, wherein the third repeating unit is different from the first repeating unit and the second repeating unit.

17. The photoresist composition of claim 9, wherein the block copolymer has a dispersity index from 1.1 to 1.4, as determined by gel permeation chromatography using polystyrene standards.

18. The photoresist composition of claim 9, wherein the block copolymer is prepared by living or controlled free radical polymerization, wherein a difunctional precursor of the center block is reacted with a first monomer to provide the first repeating unit and with a second monomer to provide the second repeating unit.
